(19) United States
(12) Patent Application Publication
(10) Pub. No.: US 2020/0126680 A1
(43) Pub. Date: Apr. 23, 2020

(54) REACTOR COOLING AND ELECTRIC POWER GENERATION SYSTEM

(71) Applicants: KOREA ATOMIC ENERGY RESEARCH INSTITUTE, Daejeon (KR); KING ABDULLAH CITY FOR ATOMIC AND RENEWABLE ENERGY, Riyadh (SA)

(72) Inventors: Youngin KIM, Daejeon (KR); Seungyeob RYU, Daejeon (KR); Joohyung MOON, Daejeon (KR); Soojai SHIN, Sejong (KR); Seok KIM, Daejeon (KR); Hyunjun CHO, Daejeon (KR); Juhyeon YOON, Daejeon (KR); Kilsung KWON, Seoul (KR)

(73) Assignees: KOREA ATOMIC ENERGY RESEARCH INSTITUTE, Daejeon (KR); KING ABDULLAH CITY FOR ATOMIC AND RENEWABLE ENERGY, Riyadh (SA)

(21) Appl. No.: 16/623,066

(22) PCT Filed: Jun. 18, 2018
(86) PCT No.: PCT/KR2018/006827

§ 371 Date: Dec. 16, 2019

(30) Foreign Application Priority Data
Jun. 19, 2017 (KR) 10-2017-0077504

(51) Int. Cl. G21C 15/18; G21C 15/25; G21D 7/04; F28D 15/02; H01L 35/32; G21C 15/12; G21C 13/02

(52) U.S. Cl. CPC G21C 15/185; G21C 15/25; G21D 7/04; G21C 13/02; H01L 35/32; G21C 15/12; F28D 15/0266

(57) ABSTRACT

A reactor cooling and power generation system according to the present invention includes a reactor vessel, a heat exchange section to receive heat generated from a core inside the reactor vessel through a fluid, and a power production section having a thermoelectric element configured to produce electric energy using energy of the fluid whose temperature has increased while receiving the heat of the reactor, wherein the system is configured to allow the fluid that has received the heat from the core to circulate through the power production section, and to operate even during an accident as well as during a normal operation of a nuclear power plant to produce electric power.

Also, the reactor cooling and power generation system according to the present invention may continuously operate during an accident as well as a normal operation so as to cool the reactor and produce emergency power, thereby improving system reliability. In addition, the reactor cooling and power generation system according to the present invention may facilitate application of safety class or seismic design with a small scale facility, thereby improving the reliability owing to the application of the safety class or seismic design.

### CROSS-REFERENCE TO RELATED APPLICATION

Pursuant to 35 U.S.C. § 119(a), this application claims the benefit of the earlier filing date and the right of priority to Korean Patent Applications No. 10-2017-0077504, filed on Jun. 19, 2017, the contents of which are incorporated by reference herein in their entirety.

### BACKGROUND

### 1. Technical Field

The present invention relates to a reactor cooling method, and more particularly, to power production using heat generated in a core and transferred to a reactor or reactor coolant system during a normal operation, emergency power production using heat generated in the core and transferred to the reactor or the reactor coolant system during an accident, and cooling of the reactor.

### 2. Description of the Related Art

Nuclear reactors are divided into loop type reactors (e.g., commercial reactors: Korea) in which major components (steam generator, pressurizer, pump, etc.) are installed outside a reactor vessel and integral reactors (e.g., SMART reactors: Korea) in which the major components are installed inside a reactor vessel.

In addition, Nuclear power plants are divided into active plants and passive plants depending on the implementation of a safety system. An active plant is a reactor using an active component such as a pump operated by electric power of an emergency diesel generator (EDG) or the like to drive a safety system, and a passive plant is a plant using a passive component operated by gravity, gas pressure or the like to drive a safety system.

A passive safety system in a passive plant may maintain the reactor in a safe manner only with a natural force built in the system without an operator action or an AC power source of safety grade such as an emergency diesel generator for more than a period of time (72 hours) required by regulatory requirements in the event of an accident, After 72 hours, using an operator action and a non-safety systems might be allowed to maintain the function of the safety systems and an emergency DC power source (battery).

Unlike a general thermal power plant where heat generation is stopped when fuel supply is stopped, a reactor in a nuclear power plant generates residual heat from a reactor core for a significant period of time by a fission product produced and accumulated during a normal operation even when a fission reaction is stopped in the reactor core. Accordingly, a variety of safety systems for removing the residual heat of the core during an accident are installed in the nuclear power plant.

In case of an active nuclear power plant (Conventional Nuclear Power Plant of Korea), a plurality of emergency diesel generators are provided in preparation for a case of interruption of electric power supply from the inside or outside at the time in an accident, and most active nuclear power plants use a pump to circulate cooling water, and thus a large-capacity emergency AC power source (a diesel generator) is provided due to the high power requirements of those active components. An operator action allowance time for an active nuclear reactor is estimated about 30 minutes.

In order to exclude active components such as a pump that requires a large amount of electricity, a driven force such as gas pressure or gravity is introduced in a passive nuclear reactor (U.S. Westinghouse AP1000, Korean SMART) that has been developed or is being developed to enhance the safety of the nuclear power plant, and thus a large amount of power is not required other than small components such as a valve, which is essentially required for the operation of a passive safety system. However, to enhance the safety in a passive nuclear power plant, an operator action allowance time is drastically extended from 30 minutes to 72 hours or longer, and an emergency active power source (diesel generator) is excluded, and an emergency DC power source (battery) is adopted. And thus the emergency DC power source should be maintained for more than 72 hours. Therefore, the emergency power source capacity required per unit time in a passive nuclear power plant is relatively small compared to an active nuclear power plant, but it is very large in terms of the battery capacity because the emergency power should be supplied for 72 hours or more.

In the other hand, a residual heat removal system (auxiliary feedwater system or passive residual heat removal system) is employed as a system for removing the heat of a reactor coolant system (the sensible heat of the reactor coolant system and the residual heat of the core) using a residual heat removal heat exchanger connected to a primary system or secondary system when an accident occurs in various nuclear power plants including an integral reactor. (AP1000: U.S. Westinghouse, commercial loop type nuclear power plant and SMART reactor: Korea)

Furthermore, a safety injection system is employed as a system for directly injecting cooling water into the reactor coolant system in case of a loss-of-coolant accident to maintain a water level of the reactor core and removing the heat of the reactor coolant system (the sensible heat of the reactor coolant system and the residual heat of the core) using the injected cooling water. (AP1000: U.S. Westinghouse, commercial loop type and SMART reactor: Korea)

Moreover, a reactor containment cooling system or spray system is a system for condensing steam using cooling or spraying to suppress a pressure rise when a pressure inside the reactor containment rises due to an accident such as a loss-of-coolant accident or a steam-line-break accident. Additionally, there are a method of directly spraying cooling water into the reactor containment (commercial loop type reactor: Korea), a method of inducing steam discharged in the reactor containment into a suppression tank (commercial boiling water reactor), a method of using a heat exchanger installed inside or outside the reactor containment (reinforced concrete containment building)) (APR+: Korea), a method of using a surface of the steel containment vessel as a heat exchanger (AP1000: U.S. Westinghouse), or the like.

As described above, various safety systems configured with multiple trains with two or more trains are installed in each system such as a residual heat removal system and a safety injection system for cooling the reactor coolant system (including the reactor vessel) to protect the reactor core at the time of an accident. However, in recent years, there has been a growing demand for safety enhancement of nuclear power plants due to the impact of Fukushima nuclear power plant (boiling water reactor) accident and the like, and thus there is a rising demand for safety facilities against a severe accident such as an external reactor vessel cooling system even in a pressurized water reactor (PWR) with a very low risk of leakage of large amounts of radioactive materials due to employing a very large-internal-volume nuclear reactor containment.

In detail, various safety facilities are provided to relieve an accident in case of the accident. In addition, each of the safety facilities is configured with multiple trains, and the probability that all systems fail simultaneously is very small. However, as a public requirement for the safety of nuclear power plants increases, safety facilities have been enhanced in preparation for a severe accident even with a very low probability of occurrence.

The external reactor vessel cooling system is a system provided to cool the outside of reactor vessel during core meltdown to prevent damage of the reactor vessel, assuming that a serious damage occurs in the core cooling function and a severe accident that the core is melted occurs since various safety facilities do not adequately perform functions due to multiple failure causes at the time of an accident. (AP1000 U.S. Westinghouse)

When the reactor vessel is damaged, a large amount of radioactive material may be discharged into the reactor containment, and a pressure inside the reactor containment may rise due to an large amount of steam generated by corium (melted core)-water reaction and gas formed by the core melt-concrete reaction. The reactor containment serves as a final barrier to prevent radioactive materials from being discharged into an external environment during an accident. When the reactor containment is damaged due to an increase in internal pressure, a large amount of radioactive material may be released to an external environment. Therefore, the external reactor vessel cooling system performs a very important function of suppressing radioactive materials from being discharged into the reactor containment and an increase of the internal pressure during a severe accident to prevent radioactive materials from being discharged into an external environment.

The external reactor vessel cooling system which is adopted in many countries is a system in which cooling water is filled in the reactor cavity located at a lower part of the reactor vessel and the cooling water is introduced into the cooling flow path in a space between the thermal insulation material and the reactor vessel and then steam is discharged to an upper part of the cooling flow path. In addition, a method of injecting a liquid metal at the time of an accident to mitigate the critical heat flux phenomenon, a method of pressurized cooling water to induce single phase heat transfer, a method of modifying a surface of the external reactor vessel to increase the heat transfer efficiency, a method of forming a forced flow, and the like, may be taken into consideration.

In the meantime, a thermoelectric element related to the present invention is an element related to a thermoelectric power generation. Thermoelectric effects related to the thermoelectric power generation include Seebeck effect 1822, Peltier effect 1834, Thomson effect 1854, and the like.

The Seebeck effect refers to a phenomenon in which current flows due to an electromotive force, which is generated when a temperature difference is caused between two contacts in a closed circuit configured by connecting two kinds of metals or semiconductors. This current is referred to as a thermoelectric current, and an electromotive force generated between metal wires is referred to as a thermoelectromotive force. A magnitude of the thermoelectric current differs depending on a type of paired metals and the temperature difference between the two contacts. In addition, electrical resistance of a metal wire is also involved to this.

The Peltier effect, in contrary to the Seebeck effect, is a phenomenon in which a temperature difference occurs due to exothermic and endothermic phenomena appearing on two surfaces when a current is applied. The Thompson effect is a phenomenon where the Seebeck effect and the Peltier effect are correlated with each other.

The thermoelectric element is an energy conversion device that directly converts heat energy into electric energy and may generate electric power without any other mechanical driving element in presence of a heat source. The thermoelectric power generation of the thermoelectric element utilizes the Seebeck effect in which two different metals are connected and an electromotive force is generated by a temperature difference between both ends, and current flows due to the exothermic and endothermic phenomenon of a thermoelectric module.

The thermoelectric power generation technology of the thermoelectric element can convert even heat near a room temperature into electric energy and thus is practical in view of recycling even low-grade waste heat as electric energy. The thermoelectric power generation is applied to a power generation using a seawater temperature difference, a power generation using solar heat, and the like, and accordingly an application range thereof is extending.

In the related art external reactor vessel cooling system, since a thermal insulation material has to perform an appropriate thermal insulation function during a normal operation of the nuclear power plant, a flow path is sealed such that inlet and outlet flow paths formed in the thermal insulating material must be properly opened in a timely manner at the time of an accident. Also, a delay time is needed to fill the reactor cavity, and the heat removal ability may be reduced due to a critical heat flux phenomenon or the like while evaporating cooling water to form a steam layer on the external reactor vessel.

In addition, there is also a research on an external reactor cooling method using a liquid metal, but the liquid metal method has difficulty in the maintenance of the liquid metal. In addition, an external reactor cooling method in a pressurization manner has difficulty in the application of a natural circulation flow, and a method of modifying a surface of a reactor vessel has difficulty in the fabrication and maintenance of the surface, and a forced flow method has a disadvantage in that it must be supplied with electric power.

On the other hand, the large-capacity steam turbine method has a large size of the facility, thus increasing the cost when a strengthened seismic design is applied thereto. Therefore, there is a limitation in being designed to produce electric power during a normal operation and during an accident of the nuclear power plant.

In addition, since the existing external reactor vessel cooling system is operated by an operator action at the time of an accident, various instruments and components for monitoring the accident are required for the operation, and probability that a system in a standby mode fails to operate at the time of an accident is higher than probability that a system being operated is stopped to operate at the time of an accident.

Accordingly, the present invention proposes a reactor cooling and electric power generation system in which the related art large-scale turbine power generation facility is maintained almost same design, and a small-scale power generation facility including the thermoelectric element is additionally installed to receive heat generated and discharged from the core during a normal operation and during an accident of the nuclear power plant.

### SUMMARY

One aspect of the present invention is to propose a reactor cooling and electric power generation system, which is easy to employ a safety grade or seismic design, and continuously operates during an accident as well as during a normal operation so as to cool the reactor and produce emergency power, thereby improving system reliability.

Another aspect of the present invention is to propose a reactor cooling and electric power generation system, capable of obtaining improved safety by removing residual heat of a predetermined scale or more even upon an occurrence of an accident as well as during a normal operation.

Still another object of the present invention is to propose a nuclear power plant having improved economic efficiency and safety owing to downsizing and reliability enhancement of an emergency power system of the nuclear power plant.

A reactor cooling and electric power generation system according to the present invention may include a reactor vessel, a heat exchange section to receive heat generated from a core inside the reactor vessel through a fluid, and a power production section having a thermoelectric element configured to produce electric energy using energy of the fluid whose temperature has increased while receiving the heat of the reactor. Also, the system may be configured to allow the fluid that has received the heat from the core to circulate through the power production section, and the system may operate even during an accident as well as during a normal operation of a nuclear power plant to produce electric power.

In an embodiment, the electric power produced during the normal operation of the nuclear power plant may be supplied to an internal/external electric power system and an emergency battery.

In an embodiment, the electric energy charged in the emergency battery may be supplied as emergency power during a nuclear accident.

Also, the electric power produced during the accident of the nuclear power plant may be supplied as emergency power of the nuclear power plant.

In an embodiment, the emergency power source may be supplied as electric power for operating a safety system of the nuclear power plant during the accident of the nuclear power plant, opening and closing a valve for the operation of the safety system, monitoring the safety system, or operating the reactor cooling and electric power generation system.

In an embodiment, seismic design of seismic categories I, II or III may be applied and safety classes 1, 2 or 3 may be applied.

In an embodiment, a first discharge portion may be provided to be connected to the heat exchange section, and the first discharge portion may be formed such that at least part of the fluid excessively supplied to the power production section bypasses the power production section.

In an embodiment, the heat exchange section may be provided to enclose at least part of the reactor vessel and may have a shape of cooling an outer wall of the reactor vessel by receiving heat discharged from the reactor vessel which has received the heat generated from the core.

Also, at least part of the heat exchange section having the shape of cooling the outer wall of the reactor vessel may have a cylindrical shape, a hemispherical shape, a double vessel shape, or a mixed shape thereof.

In the embodiment, the heat exchange section having the shape of cooling the outer wall of the reactor vessel may be connected to an in-containment refueling water storage tank (IRWST) such that refueling water is supplied thereto.

In addition, the heat exchange section having the shape of cooling the outer wall of the reactor vessel may be provided with a second discharge portion, and the second discharge portion may be formed to discharge the refueling water supplied from the in-containment refueling water storage tank (IRWST).

In an embodiment, the heat exchange section having the shape of cooling the outer wall of the reactor vessel may further be provided with a coating member to prevent corrosion of the reactor vessel.

A surface of the coating member may be chemically processed to increase a surface area thereof.

In addition, a heat transfer member may further be provided to efficiently transfer heat discharged from the reactor vessel.

A surface of the heat transfer member may be chemically processed to increase a surface area thereof.

In an embodiment, the heat exchange section may be provided inside the reactor vessel so as to cool the inside of the reactor vessel receiving heat discharged from a reactor coolant system inside the reactor vessel that has received the heat generated from the core.

In an embodiment, the heat exchange section having the shape of cooling the inside of the reactor vessel may be connected to an in-containment refueling water storage tank (IRWST) such that refueling water is supplied thereto.

In addition, the heat exchange section having the shape of cooling the inside of the reactor vessel may be provided with a second discharge portion, and the second discharge portion may be formed to discharge the refueling water supplied from the in-containment refueling water storage tank (IRWST).

In an embodiment, the system may further include an evaporation section connected to the heat exchange section. The evaporation section may be formed to cause heat exchange between an inner fluid of the heat exchange section and an inner fluid of the power production section. The system may further include a first circulation unit extending from the heat exchange section to the evaporation section such that a fluid circulates therealong, and a second circulation part extending from the evaporation section to the power production section such that a fluid circulates therealong.

In an embodiment, at least one of the first circulation part and the second circulation part may be formed such that a single-phase fluid circulates therealong.

In an embodiment, the heat exchange section may further include a core catcher, and the core catcher may be provided to receive and cool a corium when the core inside the reactor vessel is melt down.

In an embodiment, the thermoelectric element of the power production section may include a high-temperature part to receive heat from the heat exchange section, a low-temperature part to dissipate heat received from the high-temperature part to outside, and a power production part to produce power using an electromotive force generated by a temperature difference between the high-temperature part and the low-temperature part.

In an embodiment, a coating member may be further provided on a surface of the high-temperature part or the low-temperature part to prevent corrosion of the high-temperature part or the low-temperature part.

A surface of the coating member may be chemically processed to increase a surface area thereof.

In an embodiment, the thermoelectric element may be further provided with a heat transfer member to efficiently transfer heat discharged from the high-temperature part or the low-temperature part.

A surface of the heat transfer member may be chemically processed to increase a surface area thereof.

In an embodiment, the system may further include a condensed water storage section provided at a lower portion of the power production section to collect condensed water generated by condensing the fluid heat-exchanged in the power production section.

The condensed water in the condensed water storage section may be supplied to the heat exchange section by gravity or by a driving force of a pump.

A nuclear power plant according to the present invention may include a reactor vessel, a heat exchange section to receive heat generated from a core inside the reactor vessel through a fluid, and a power production section having a thermoelectric element configured to produce electric energy using energy of the fluid whose temperature has increased while receiving the heat of the reactor. The nuclear power plant may allow the fluid that has received the heat from the core to circulate through the power production section, and operate during a normal operation and even during an accident thereof to produce electric power.

A reactor cooling and electric power generation system according to the present invention is configured to drive a power production section including a thermoelectric element, which is configured to produce electric energy using energy of a fluid, by using a small-scale facility. A heat exchange section and a power production section of the present invention may continuously operate even during an accident as well as a normal operation so as to cool residual heat and produce emergency power, thereby improving system reliability. The system can easily employ a safety grade or seismic design and improve reliability of a nuclear power plant by including a heat exchange section, which is provided with the safety grade or seismic design and continuously operates even during an accident as well as a normal operation so as to cool the reactor.

The reactor cooling and electric power generation system according to the present invention may be designed to remove residual heat of a predetermined scale or more generated from a core of the reactor, and continuously operate not only during a normal operation but also during an accident to reduce probability of actuation failure at the time of an accident, thereby improving safety of the nuclear power plant.

A nuclear power plant according to the present invention can have improved economic efficiency by way of reducing a size of an emergency power system using the reactor cooling and electric power generation system.

### BRIEF DESCRIPTION OF THE DRAWINGS

FIG. 1A is a conceptual view of a reactor cooling and power generation system in accordance with an embodiment of the present invention.

FIG. 1B is a conceptual view illustrating an operation of a reactor cooling and power generation system according to an embodiment of the present invention during a normal operation.

FIG. 1C is a conceptual view illustrating a forced circulation operation of a reactor cooling and power generation system according to an embodiment of the present invention during a nuclear design basis accident.

FIG. 1D is a conceptual view illustrating a natural circulation operation of a reactor cooling and power generation system according to an embodiment of the present invention during a nuclear design basis accident.

FIG. 1E is a conceptual view illustrating an operation of a reactor cooling and power generation system according to an embodiment of the present invention during a severe accident of a nuclear power plant.

FIG. 2A is a conceptual view of a reactor cooling and power generation system in accordance with another embodiment of the present invention.

FIG. 2B is a conceptual view illustrating an operation of a reactor cooling and power generation system according to another embodiment of the present invention during a nuclear normal operation.

FIG. 2C is a conceptual view illustrating a forced circulation operation of a reactor cooling and power generation system according to an embodiment of the present invention during a nuclear design basis accident.

FIG. 2D is a conceptual view illustrating a natural circulation operation of a reactor cooling and power generation system according to an embodiment of the present invention during a nuclear design basis accident.

FIG. 2E is a conceptual view illustrating an operation of a reactor cooling and power generation system according to an embodiment of the present invention during a severe accident of a nuclear power plant.

FIGS. 3A to 3E are conceptual views of a reactor cooling and power generation system in accordance with still another embodiment of the present invention.

FIG. 4 is a conceptual view of a reactor cooling and power generation system in accordance with still another embodiment of the present invention.

FIGS. 5A to 5C are conceptual views of a reactor cooling and power generation system in accordance with yet still another embodiment of the present invention.

FIGS. 6A to 6C are views specifically illustrating a heat exchange section of FIGS. 5A to 5C.

FIG. 7A is a top sectional view of the heat exchange section cut along line A-A′ in FIG. 6A.

FIG. 7B is a middle sectional view of the heat exchange section cut along line B-B′in FIG. 6A.

FIG. 7C is a bottom sectional view of the heat exchange section cut along line C-C′ in FIG. 6A.

FIG. 8 is a conceptual view illustrating a detailed structure of a thermoelectric element applied to a reactor cooling and power generation system according to the present invention.

### DETAILED DESCRIPTION OF THE EMBODIMENTS

Description will now be given in detail according to exemplary embodiments disclosed herein, with reference to the accompanying drawings. For the sake of brief description with reference to the drawings, the same or equivalent components may be provided with the same or similar reference numbers, and description thereof will not be repeated. In describing the present invention, moreover, the detailed description will be omitted when a specific description for publicly known technologies to which the invention pertains is judged to obscure the gist of the present invention. The accompanying drawings are used to help easily understand the technical idea of the present invention and it should be understood that the idea of the present invention is not limited by the accompanying drawings. The idea of the present invention should be construed to extend to any alterations, equivalents and substitutes besides the accompanying drawings.

It will be understood that although the terms first, second, etc. may be used herein to describe various elements, these elements should not be limited by these terms. These terms are generally only used to distinguish one element from another.

A singular representation may include a plural representation unless it represents a definitely different meaning from the context.

Terms such as “include” or “has” are used herein and should be understood that they are intended to indicate an existence of several components, functions or steps, disclosed in the specification, and it is also understood that greater or fewer components, functions, or steps may likewise be utilized.

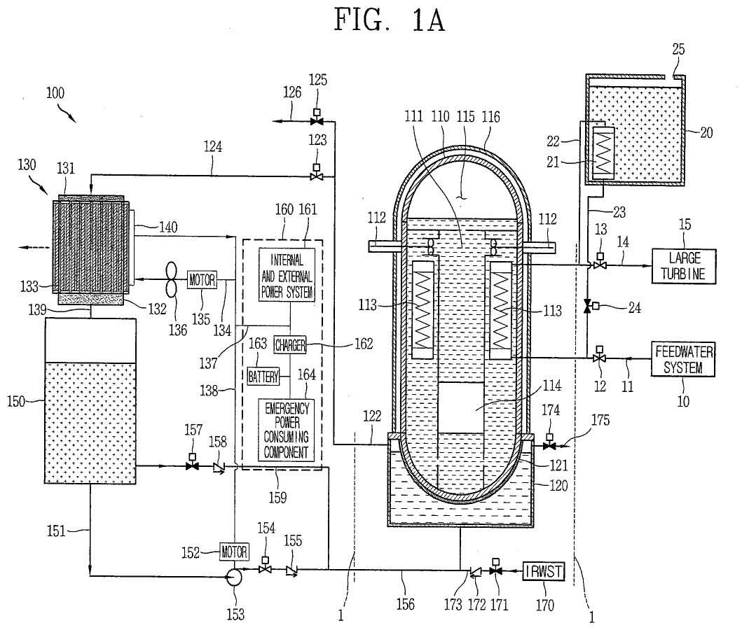

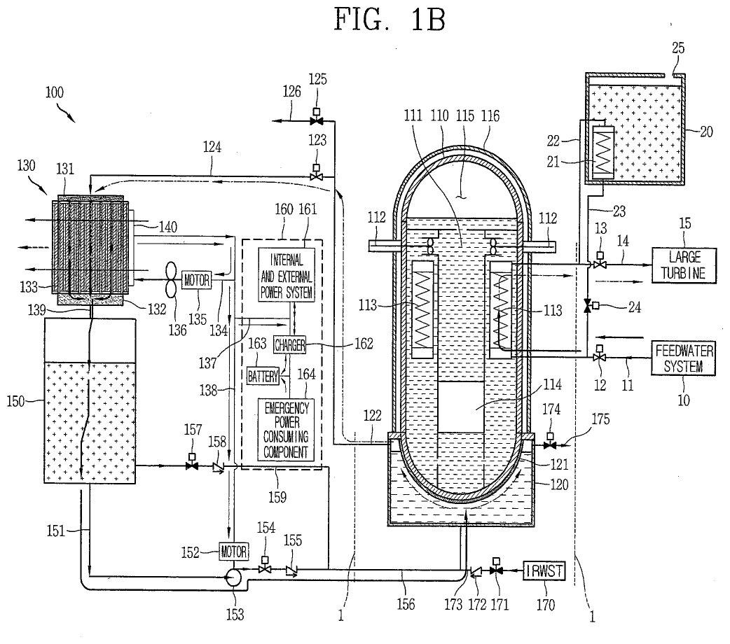

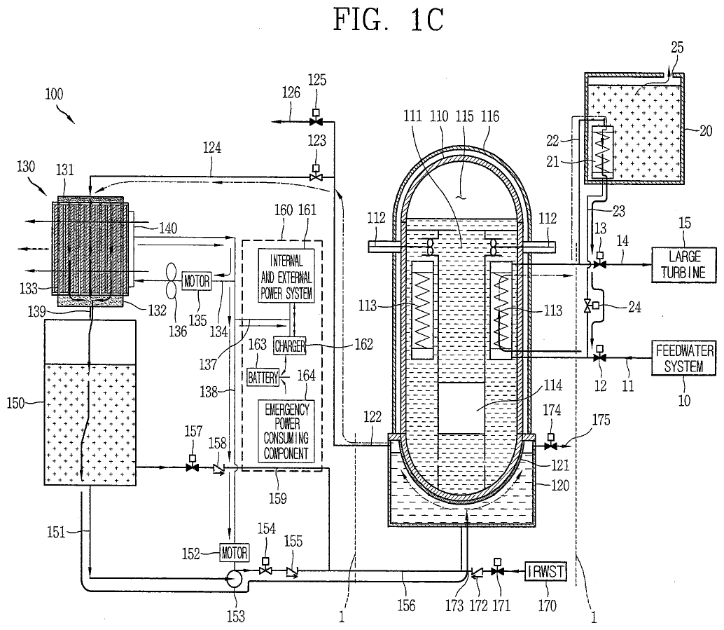

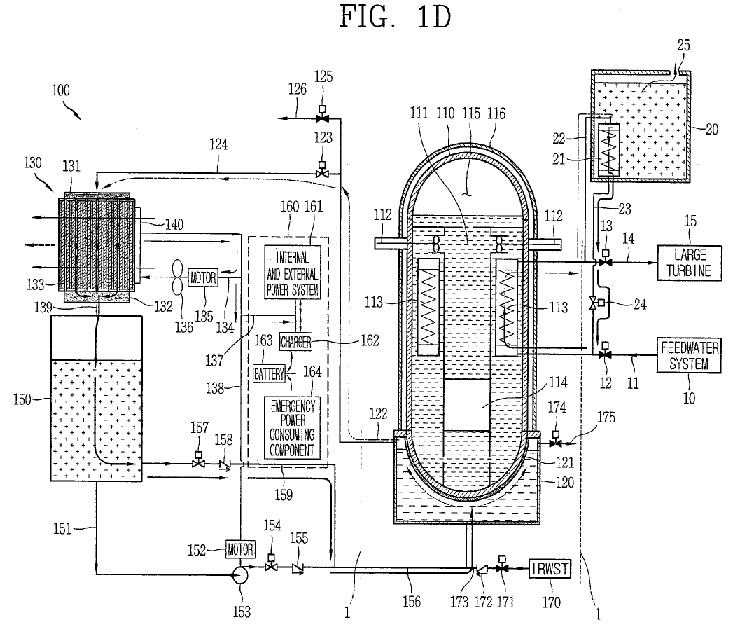

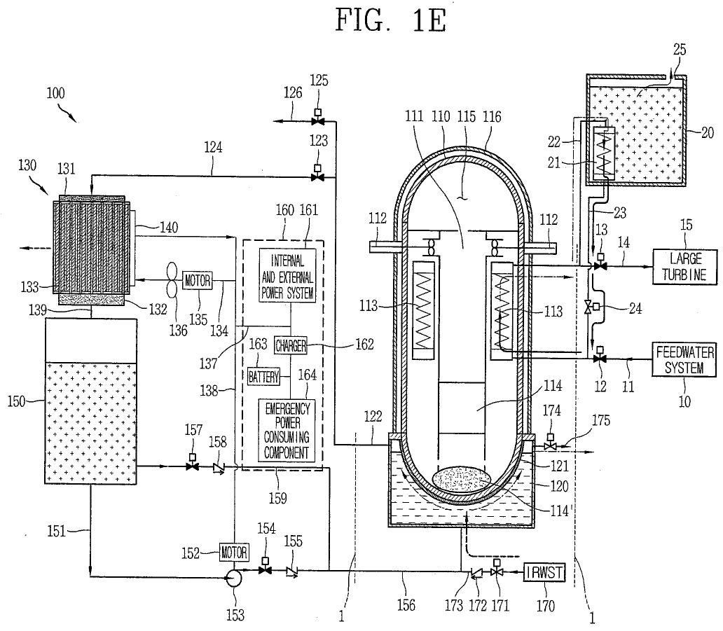

Hereinafter, a reactor cooling and power generation system provided with an heat exchange section 120, 220, 320a, 320b, 320c, 320d, 320e, 420 having a shape capable of cooling an external reactor vessel formed to receive heat discharged from a reactor vessel that has received heat generated in a core to operate even during a normal operation and during an accident of the nuclear power plant so as to produce power will be described in more detail with reference to FIGS. 1A to 1E, FIGS. 2A to 2E, FIGS. 3A to 3E, and FIG. 4.

FIG. 1A is a conceptual view of a reactor cooling and power generation system 100 in accordance with an embodiment of the present invention.

In an embodiment of the present invention, the reactor coolant system 111 may be circulated inside the reactor vessel 110. In addition, a heat insulator 116 surrounding a part of the reactor vessel 110 may be formed. Furthermore, the inside of the reactor vessel 110 may be formed to have a core 114. The core 114 refers to nuclear fuel. The reactor vessel 110 may be a pressure vessel designed to withstand high temperatures and pressures because electric power is produced by heat generated while performing fission in the core 114.

When an accident occurs in a nuclear power plant, residual heat may be generated for a considerable period of time even when the core 114 is stopped because a control rod is inserted in the core 114. When it is assumed that various safety and non-safety systems do not operate at the time of an accident of the nuclear power plant though having a very low probability of occurrence, cooling water inside the reactor vessel 110 may be lost to increase the temperature of the nuclear fuel, thereby causing a core meltdown phenomenon.

On the other hand, during a normal operation of the nuclear power plant, heat may be received from the reactor coolant system 111 to produce steam. The steam generator 113 may be a pressurized light water reactor. Further, the steam produced by the steam generator 113 may be steam that is phase-changed by receiving water through a main feedwater line 11 connected to a feedwater system 10 and an isolation valve 12. The steam produced by the steam generator 113 may be passed through a main steam line 14 connected to an isolation valve 13 and supplied to a large turbine 15 and a large generator (not shown) to produce electric power while the fluid energy of the steam is converted into electric energy through mechanical energy. However, although the pressurized water reactor is illustrated in the present invention, the technology of the present invention is not limited to the pressurized water reactor.

In addition, a reactor coolant pump 112 may circulate coolant that fills the inside of the reactor vessel 110. A pressurizer 115 provided inside the reactor vessel 110 may control pressure of the reactor coolant system 111.

Moreover, a passive residual heat removal system including an emergency cooling water storage section 20 and a heat exchanger 21 may be provided therein to discharge the heat of the reactor coolant system 111 to the emergency cooling water storage section 20 through the steam generator by natural circulation due to a two-phase flow received through lines 22, 23 and the opening and closing of a valve 24 during an accident. Further, when steam is generated while emergency cooling water is evaporated by heat transferred to the emergency cooling water storage section 20, the steam may be released through a steam discharge portion 25 to discharge the transferred heat to the atmosphere.

The reactor cooling and power generation system 100 is in an operation state even during a normal operation and heat is continuously transferred to the reactor vessel 111 by residual heat generated from the core 114 until the temperature of the reactor vessel 110 is significantly reduced to reach a safe state, and thus the reactor cooling and power generation system 100 continues to operate.

Accordingly, an operator action for the reactor cooling operation, various measuring instruments and control systems, valve operation or pump start and the opening and closing of a thermal insulation material may not be required as in the related art method, and thus probability of operation failure of the reactor cooling and power generation system 100 is greatly reduced to improve the safety of the nuclear power plant.

In addition, since emergency power can be stably produced by the reactor cooling and power generation system 100 until the temperature of the reactor vessel is reduced to reach a safe state during an accident, the capacity of an emergency DC battery may be decreased to improve the economic efficiency of the nuclear power plant and improve the reliability of an emergency power system of the nuclear power plant by securing the emergency power supply means of a safety system, thereby improving the safety of the nuclear power plant.

In detail, in case of a passive nuclear power plant, emergency power required during an accident is less than about 0.05% compared to the power generation capacity generated from the nuclear power plant during a normal operation. However, it is designed to use a battery for 72 hours or more, and thus a very large battery is required, having a disadvantage of increasing the cost. However, the reactor cooling and power generation system 100 may produce an appropriate level of emergency power using residual heat continuously generated from the core 114 (an amount of residual heat generated is several % (initial shutdowm) to 1/several % (after 72 hours subsequent to shutdown) compared to a normal amount of thermal power).

Moreover, when power is produced using the in-vessel cooling and power generation system 100, the power production amount is several tens of kWe to several MWe, and the capacity is less than 1/several % compared to the feedwater system 10 and the large turbine 15 for a normal operation of the nuclear power plant. This system 100 has almost no influence on the operation of nuclear power plant, and therefore, even when this system 100 fails during a normal operation. Than is to say, this system 100 has a capacity less than 1/several %, so it has little effect on a nuclear power plant operation.

In addition, when power is produced using the reactor cooling and power generation system 100, it may be constructed in a small scale compared to the large capacity feedwater system 10 and the large turbine 15 for producing normal power, and therefore, it is easy to apply seismic design and safety class, and cost increase is not so great due to small facilities even when seismic design and safety class are applied.

Besides, even in the event of an accident, it operates continuously as a normal operation without any additional valve operation, and therefore, during an accident, the probability of operation failure of valves, pumps, and the like for the actuation of the reactor cooling system in the related art, and the probability of operation failure or breakdown due to an error measuring instruments and control signals may be significantly reduced.

Moreover, when the heat exchange section 120 and the power (electric power) production section 130 may do not work during the occurrence of a severe accident, a flow path through the in-containment refueling water storage tank (hereinafter, referred to as IRWST) 170 and the first discharge portion 175 is already formed, and therefore, the supply and discharge of cooling water can be smoothly carried out by a simple operation such as opening or closing a valve according to an operator action, and such cooling water can also be used for the cooling of the reactor coolant system 111 including the reactor vessel 110 and corium (core melt).

In particular, in case of an integral reactor, a lower space of the inner and outer reactor vessel has a simple structure, and the lower or other space of the inner and outer reactor vessel is easily secured, and thus it is easier to apply the reactor cooling and power generation system 100 of the present invention.

In addition, the reactor cooling and power generation system 100 may be used as an additional residual heat removal means that performs the role of removing the residual heat of the reactor core 114 during an accident.

Hereinafter, the reactor cooling and power generation system 100 according to the present invention will be described in detail.

The inside of the reactor containment boundary 1 (not shown) (hereinafter also referred to as a containment or reactor containment) may include a reactor vessel 110, a heat exchange section 120, and an IRWST 170.

The heat exchange section 120 may be configured to receive heat generated from the core 114 inside the reactor vessel 110 through a fluid. In an embodiment, the heat exchange section 120 may be configured to enclose at least a part of the reactor vessel 110. In other words, the heat exchange section 120 may be configured to receive heat discharged from the reactor vessel 110 and cool the outer wall of the reactor vessel 110.

On the other hand, the outside of the reactor containment boundary 1 includes a power production section 130 and a condensed water storage section 150. The power production section 130 may be connected to the motors 135, 152 and the power system 160 to supply power. The power system 160 may include an internal/external electric power system 161, a charger 162, an emergency power consuming device 164, and an emergency battery 163. However, some of the components illustrated as being installed outside the reactor containment boundary 1 may be disposed inside the reactor containment boundary 1 depending on the layout characteristics of the nuclear power plant.

The reactor vessel 110 formed inside the reactor containment boundary 1 may be a pressure vessel which is configured to circulate the reactor coolant of the reactor coolant system 111 and includes the core 114 therein. The reactor vessel 110 may be designed to withstand high pressure.

The heat exchange section 120 is provided outside the reactor vessel 110 to receive heat transferred from the reactor coolant system 111 to the reactor vessel 110 at an outside of the reactor vessel 110. In detail, residual heat produced in the core 114 may be transferred to an inner surface of the reactor vessel 110 through the circulation of the reactor coolant system 111, and the transferred heat may be transferred to an outer surface of the reactor vessel 110 by the conduction heat transfer of the reactor coolant system 110 and then transferred to the heat exchange section 120, thereby allowing the heat exchange section 120 to perform cooling for the reactor vessel 110. In other words, the heat exchange section 120 may perform cooling for the reactor vessel 110 and reactor coolant inside the reactor vessel 110 during a normal operation of the nuclear power plant, and perform cooling for the reactor vessel 110, reactor coolant and the corium during a nuclear accident.

In an embodiment, the heat exchange section 120 may be formed to enclose a lower portion of the reactor vessel 110 and may be a heat exchange section having a shape capable of cooling the outer wall of the reactor vessel 110 using a fluid that receives heat discharged from the reactor vessel 110.

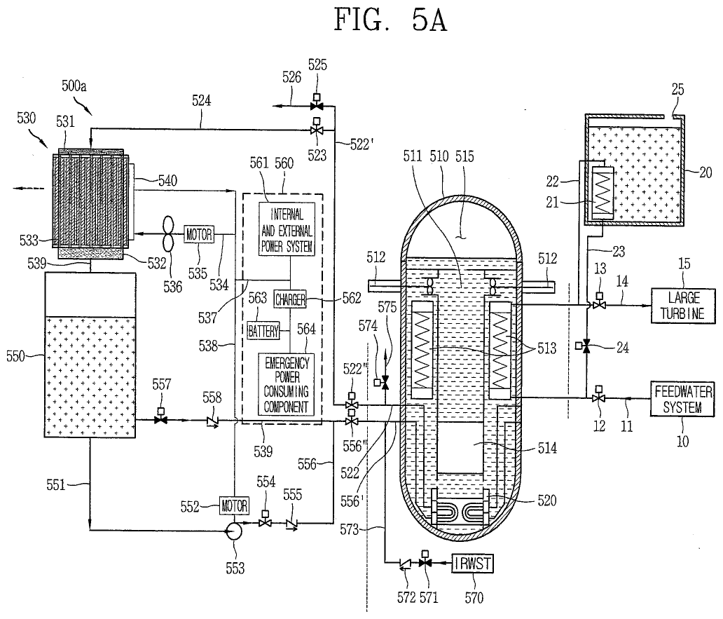

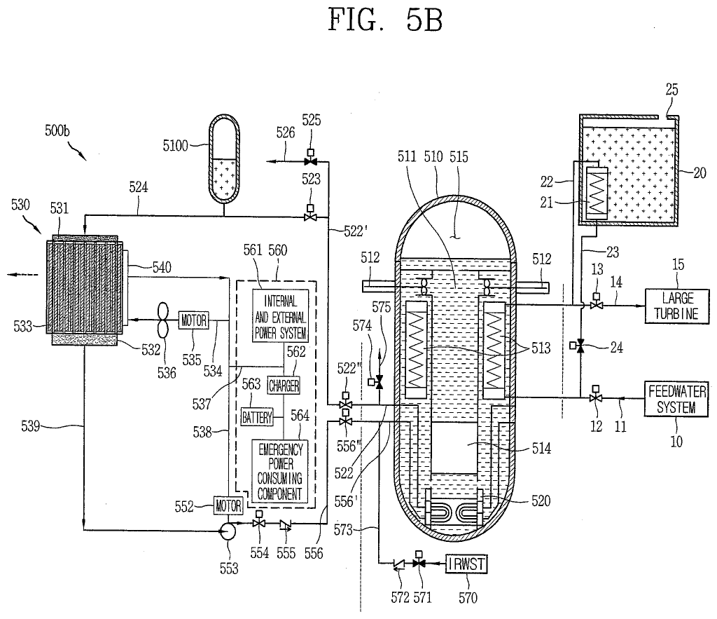

In still another embodiment, the heat exchange section may be provided inside the reactor vessel 110 and may be a heat exchange section having a shape provided inside the reactor vessel to receive heat from the reactor coolant system 111 inside the reactor vessel 110 that has received heat generated from the core 114. The heat exchange section having the shape of the heat exchange section provided inside the reactor vessel will be described later with reference to FIGS. 5A to 5C, 6A to 6C, and 7A to 7C.

In an embodiment, when the heat exchanging section 120 is a heat exchanging section having a shape capable of cooling the outer wall of the reactor vessel 110, the shape of the heat exchange section 120 may be cylindrical. However, the shape of the heat exchange section 120 is not limited to the cylindrical shape, and at least a part of the heat exchange section 120 may include a cylindrical shape, a hemispherical shape, and a double vessel shape. In addition, the heat exchange section 120 having the shape capable of cooling the outer wall of the reactor vessel may further include a coating member 121 for preventing corrosion or increasing heat transfer efficiency.

In an embodiment, the surface of the coating member 121 may be reformed in various ways, and may also be processed in an uneven shape (cooling fin) to increase the heat transfer surface area. Further, the coating member 121 may further include a heat transfer member (not shown) whose surface is chemically processed to increase a surface area so as to improve heat transfer efficiency. That is, the surfaces of the coating member 121 and the heat transfer member may be chemically processed to increase the surface areas thereof, such that the heat transfer can be efficiently carried out.

In addition, the heat exchange section 120 is provided with a discharge pipe 122, and the discharge pipe 122 may be connected to the heat exchange section 120 and the power production section 130 to supply the fluid of the heat exchange section 120 to the power production section 130. The discharge pipe 122 may be branched to a pipe 124 passing through the valve 123 and connected to the power production section 130.

The discharge pipe 122 may include a first discharge portion 126 connected to the valve 125, and the first discharge portion 126 may be formed to discharge at least part of the fluid excessively supplied to the power production section 130 or allow it to bypass the power production section 130. Specifically, the first discharge portion 126 may be configured to discharge a part of fluid (gas, steam) when pressure of the system rises or the fluid (liquid) is excessively supplied to a pipe for discharging the fluid (gas, steam) from the heat exchange section 120 to the outside of the reactor containment (not shown). In the present invention, the first discharge portion 126 is illustrated to discharge a fluid to the outside of the reactor containment (not shown) but may also be configured to allow the discharged fluid to bypass the power production section 130 and then condensate the fluid for reuse according to the characteristics of the nuclear power plant.

Moreover, the heat exchange section 120 may be connected to the IRWST 170 to supply refueling water through the pipe 173. In detail, the IRWST 170 may be connected to a valve 171 and a check valve 172. As a result, a second discharge portion 175 connected to the valve 174 may be provided to discharge the refueling water supplied from the IRWST 170 to the pipe 173 through the second discharge portion 175 during an accident.

Specifically, the second discharge portion 175 is a pipe through which the refueling water supplied from the IRWST 170, namely, a fluid (gas/steam, a mixture of gas/steam and liquid/hot water, or liquid/hot water) is discharged into the reactor building (not shown). The second discharge portion 175 is configured to cool the inside and outside of the reactor vessel 110 even when cooling and power generation using the heat exchange section 120 and the power production section 130 are not carried out due to a failure of the heat exchange section 120 and the power production section 130 caused by a severe accident.

Meanwhile, the fluid may be transferred and injected into the power production section 130 from the heat exchange section 120. The power production section 130 may be configured to produce electric energy using heat energy of the fluid and may include a thermoelectric element 133.

In detail, the power production section 130 may include a high-temperature part 131 and a low-temperature part 132 that are formed in a shape of a flow path in order to produce electric energy through the thermoelectric element 133. In detail, the power production section 130 may include a high-temperature part 131 along which a fluid receiving heat from the heat exchange section 120 flows, and a low-temperature part 132 through which heat received from the high-temperature part 131 is dissipated to the outside.

On the other hand, the low-temperature part 132 may dissipate the heat, which is received from the high-temperature part 131 through the thermoelectric element 133, using a fluid (air, fresh water or seawater) of an external environment having a temperature lower than that of the fluid supplied to the high-temperature part 131. In detail, the low-temperature part 132 may be provided with a fan 136 or a pump (not shown), by which the fluid of the external environment is supplied to the low-temperature part 142 so as to exchange heat with the fluid supplied to the high-temperature part 131. In detail, the fan 136 or the pump may be operated by supplying electric power produced by the power production part 140 of the power production section 130 to the motor 135 through a connection line 134. In addition, the power generated by the power production part 140 may be supplied to the power system 160 through the connection line 137.

The power production section 130 includes a power generation part 140 that is configured to generate power using an electromotive force generated in the thermoelectric element 133 by a temperature difference between the high-temperature part 131 and the low-temperature part 132. Further, a radiating fin (not shown) may be further provided to increase a surface area of the high-temperature part 131 or the low-temperature part 132 so as to increase heat transfer efficiency.

In detail, the thermoelectric element 133 may constitute a closed circuit using a dissimilar metal or semiconductor (P-type semiconductor or N-type semiconductor) and may employ a thermoelectric power generation technology using the Seebeck effect in which current flows due to an electromotive force which is generated between two contacts by the temperature difference between the high-temperature part 131 and the low-temperature part 132.

In the present invention, the partial shape of the thermoelectric element 133 of the power production section 130 has been illustrated. However, the power production using the thermoelectric element 133 is not limited to the proposed method, but thermoelectric element 133 of the present invention may be configured in various forms.

In an embodiment, electric power produced in the power production section 130 may be variable in consideration of a heat transfer rate due to heat generated in the core 114 supplied during an accident to control a load of the power production section 130 according to the heat transfer rate.

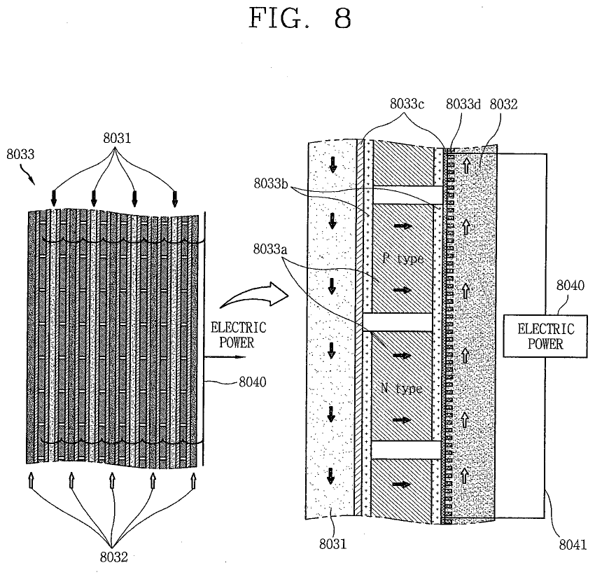

In addition, the power production section 130 may be a small-capacity power production facility including the thermoelectric element 133, which may make it easy to apply seismic design or safety class to be described later. The thermoelectric element applied to the reactor cooling and power generation system of the present invention will be described in detail with reference to FIG. 8.

The electric power that can be generated by the power production section 130 has a capacity of several tens of kWe to several MWe, which is less than 1% compared to the large-capacity feedwater system 10 and the large turbine 15 for producing the normal power of the nuclear power plant, and even when the facility operates or fails, there is little influence on the operation of the large capacity feedwater system 10 and the large turbine 15 for producing normal nuclear power.

In other words, the large capacity feedwater system 10 and the large turbine 15 for producing normal power are one of the biggest large-scale facilities of the nuclear power plant, and applying the seismic design and safety class above a certain scale to the whole facilities is very uneconomical because it causes a huge cost increase. On the other hand, in case of the reactor cooling and power generation system 100 to which the thermoelectric element 133 is applied, a size of the system 100 is much smaller than that of the feedwater system 10 and the large turbine 15, and thus it is easy to apply seismic design or safety class thereto, and costs increased by applying the seismic design or safety class is not so great. The thermoelectric element 133 and the power production part 140 may continuously operate to supply emergency power even when it is difficult to supply power due to an occurrence of an earthquake since seismic design is applied to the reactor cooling and power generation system 100. Also, the thermoelectric element 133 and the power production part 140 may continuously operate to supply emergency power even when various accidents occur since safety class is applied to the reactor cooling and power generation system 100 to secure system reliability.

Considering that electric power required during an accident in a passive nuclear power plant is several tens kWe although the emergency power is different according to characteristics of nuclear power plants, sufficient power can be supplied with only electric power produced by the thermoelectric element 133 and the power production part 140. Besides, since the emergency DC battery capacity of the passive nuclear power plant is not greater than emergency power required by an active nuclear power plant, the DC battery may be recharged by power produced by the operation of the thermoelectric element 133 and the power production part 140.

The reactor cooling and power generation system 100 may be formed to have a seismic design of seismic category I to III specified by ASME (American Society of Mechanical Engineers). Specifically, seismic category I is applied to structures, systems and components classified as safety items, and should be designed to maintain an inherent “safety function” in case of a safe shutdown earthquake (SSE), and the safety function is maintained even under the operating basis earthquake (OBE) in synchronization with a normal operation load, and the appropriate allowable stresses and changes are designed to be within limits.

Though not requiring nuclear safety or continuous functions, seismic category II is applied to items whose structural damages or interaction may lower the safety functions of the structures, systems and components of the seismic category I or cause damage to an operator located within a main control room. In detail, the structures, systems and components belonging to the seismic category II are not required to have functional integrity for the SSE but required only to have structural integrity. In addition, the structures, systems and components of the seismic category II should be designed and arranged so as not to impair safety-related operations of the items belonging to the seismic category I.

Seismic category III is designed according to uniform building codes (UBCs) or general industrial standards according to the individual design function.

The reactor cooling and power generation system 100 may be configured to have a safety rating of safety ratings 1, 2 or 3 of the reactor plant specified by the American Society of Mechanical Engineers (ASME). In detail, the safety class of a nuclear power plant is typically divided into safety class 1 through safety class 3.

Safety class 1 is a class assigned to a RCS (reactor coolant system) pressure-boundary portion of a facility and its support that constitute a reactor coolant pressure boundary (a portion that may result in a loss of coolant beyond a normal make-up capacity of the reactor coolant in the event of a failure).

Safety class 2 may be assigned to a pressure-boundary portion of the reactor containment building and its support, and assigned to a pressure-resistant portion of a facility and its support that perform the following safety functions while not belonging to safety class 1.
A function of preventing the release of fission products or containing or isolating radioactive materials in the containment building
A function of removing heat or radioactive materials generated in the containment building in case of an emergency (e.g., containment building spray system) and a function of increasing negative reactivity to make the reactor in a subcritical state in case of an emergency or suppressing an increase of positive reactivity through a pressure boundary facility (e.g., boric acid injection system)
A function of supplying coolant directly to the core during an emergency to ensure core cooling (e.g., residual heat removal, emergency core cooling system) and a function of supplying or maintaining sufficient reactor coolant for cooling the reactor core during an emergency (e.g., refueling water storage tank)

Safety class 3 is not included in safety classes 1 and 2, and may be assigned to a facility that performs one of the following safety functions:
A function of controlling concentration of hydrogen in the reactor containment building within an allowable limit
A function of removing radioactive materials from a space (e.g., main control room, nuclear fuel building) outside the reactor containment building with safety class 1, 2 or 3 facilities
A function of increasing negative reactivity to make or maintain the reactor in a subcritical state (e.g., boric acid make-up)
A function of supplying or maintaining sufficient reactor coolant for core cooling (e.g., Reactor coolant replenishment system)
A function of maintaining a geometric structure inside the reactor to ensure core reactivity control or core cooling capability (e.g., core support structure)
A function of supporting or protecting the load for safety class 1, 2 or 3 facilities (concrete steel structures not included in KEPIC-MN, ASME sec. III)
A function of shielding radiation for people outside the reactor control room or nuclear power plant
A cooling maintenance function of spent wet storage fuel (e.g., spent fuel vault and cooling system)
A function of ensuring safety functions performed by safety class 1, 2 or 3 facilities (e.g., a function of removing heat from safety class 1, 2 or 3 heat exchangers, safety class 2 or 3 pump lubrication function, a fuel feeding function of emergency diesel engine)
A function of supplying activation electric power or motive power to safety class 1, 2 or 3 facilities
A function of allowing safety class 1, 2 or 3 facilities to provide information for manual or automatic operation required for the performance of safety functions or controlling the facilities
A function of allowing safety class 1, 2 or 3 facilities to supply power or transmit signals required for the performance of safety functions
Manual or automatic interlocking function to ensure or maintain safety class 1, 2 or 3 facilities to perform appropriate safety functions
A function of providing appropriate environmental conditions for safety class 1, 2 or 3 facilities and an operator
A function corresponding to safety class 2 to which standards for the design and manufacture of pressure vessels, KEPIC-MN, ASME Sec. III, are not applied

On the other hand, a fluid discharged through heat exchange with the high-temperature part 131 is transferred to the condensed water storage section 150 along the pipe 139. In detail, the condensed water storage section 150 may be disposed at a lower portion of the power production section 130 to collect condensed water being condensed and discharged while exchanging heat with the fluid of the high temperature section 131. However, in an embodiment of the present invention, the condensed water generated while the fluid passes through the hot-temperature part 131 may be transferred to the condensed water storage section 150 by gravity. However, according to characteristics of nuclear power plants, a pump (not shown) may be installed between the pipe 139 and the condensed water storage section 150 to forcibly transfer the condensed water.

The condensed water collected in the condensed water storage section 150 may circulate through the heat exchange section 120 and the power production section 130. Moreover, the condensed water storage section 150 may be connected to the heat exchange section 120 and the pipe 156 to supply the condensed water to the heat exchange section 120.

The condensed water may be supplied to the pipe 156 through the pipes 159 and 151 connected to the condensed water storage section 150. Specifically, the condensed water in the condensed water storage section 150 may also be supplied to the pipe 156 connected to the heat exchange section 120 through the valve 154 and the check valve 155 by the motor 152 and the small pump 153 connected to the pipe 151. On the other hand, the condensed water may be supplied to the pipe 156 connected to the heat exchange section 120 by gravity through the valve 157 and the check valve 158 connected to the pipe 159 of the condensed water storage section 150.

The motor 152 may be supplied with electric power produced by the power production section 130 itself through a connection line 138. In addition, the motor 152 may be provided to charge electric power produced by the power production section 130 to the emergency battery 163 and receive electric power from the emergency battery 163.

On the other hand, in another embodiment, a fluid exchanging heat with the low-temperature part 132 through the pipe 124 may be driven by a single-phase fluid that does not undergo phase change due to heat discharged from the core 114. When the single-phase fluid circulating through the heat exchange section 120 and the power production section 130 is gas, the gaseous fluid may circulate without the condensed water storage section. Moreover, when the single-phase fluid is a liquid, the liquid may circulate through the heat exchange section 120 and the power production section 130 without the condensed water storage section described above with the aid of a pressurizer and a pressure control section.

The power system 160 may be configured to use the power produced during the normal operation of the nuclear power plant as power of the internal/external electric power system 161. In detail, the internal/external electric power system 161 may be a system for processing electricity supplied from an on-site large turbine generator, the power production section 130, an on-site diesel generator, and an external electric power grid.

In addition, electric energy may be stored in the emergency battery 163 through a charger 162, which is a facility for storing alternating current (AC) electricity supplied from the on-site, the outside, or the power production section 130 or the like. The emergency battery 163 may be a battery provided in a nuclear power plant on-site to supply emergency DC power used during an accident.

Further, the electric energy stored in the emergency battery 163 may be supplied to the emergency power consuming device 164 and used as emergency power. The emergency power may be used as power for operating the nuclear power plant safety system, opening or closing a valve for the operation of the nuclear power plant safety system, or monitoring the nuclear safety system during an accident of the nuclear power plant. Moreover, the electric power produced by the power production section 130 during an accident of the nuclear power plant may also be supplied as emergency power of the nuclear power plant.

Moreover, when the heat exchange section 120 and the power production section 130 fail due to the occurrence of a severe accident, a flow path through the IRWST 170 and the first discharge portion 175 is already formed, and therefore, such that supply and discharge of cooling water can be smoothly carried out by a simple operation such as opening or closing a valve according to an operator action to cool the reactor vessel 110.

FIG. 1B is a conceptual view illustrating an operation of a reactor cooling and power generation system 100 according to an embodiment of the present invention during a normal operation of a nuclear power plant.

Referring to FIG. 1B, it is a conceptual view illustrating system arrangement and supercritical fluid flow during a normal operation of the nuclear power plant. During the normal operation of the nuclear power plant, main feedwater (water) is supplied from the feedwater system 10 to the steam generator 113, and heat received from the core 114 by the reactor coolant circulation of the reactor coolant system 111 is transferred to a secondary system through the steam generator 113 so as to increase a temperature of the main feedwater and produce steam. The steam produced from the steam generator 113 is supplied to the large turbine 15 along the main steam line 14 to rotate the large turbine 150 and rotate the large generator (not shown) connected through the shaft to produce electric power. The power produced through the large generator may be supplied to an on-site or off-site from the power system.

Meanwhile, feedwater supplied from the small pump 153 to the heat exchange section 120 through the pipe 156 may receive heat while moving upward along the outer wall of the reactor vessel 110 to produce steam. The steam may be supplied to the power production section 130 including the thermoelectric element 133 along the discharge pipe 122 disposed at an upper portion of the heat exchange section 120, and thermal energy of the steam may cause a temperature difference between both ends of the thermoelectric element 133 to generate an electromotive force. The power generation part 140 may collect the electromotive force to produce power.

Further, the electric power produced by the power production section 130 may be used by the power system 160 as the electric power of the internal/external electric power system 161. In addition, electric energy may be stored as emergency power in the emergency battery 163 through a charger 162, which is a facility for storing alternating current (AC) electricity supplied from the on-site, the outside, or the power production section 130 or the like. The emergency battery 163 may be a battery provided in the on-site to supply emergency DC power used during an accident. The electric power may also be supplied to the emergency power consuming device 164 to be used as emergency power.

In addition, the fluid may be cooled and condensed by transferring heat to the thermoelectric element 133 while moving along the hot-temperature part 131, thereby generating condensed water. The condensed water may be collected in the condensed water storage section 150 along the pipe 139. The condensed water collected in the condensed water storage section 150 may circulate through the heat exchange section 120 and the power production section 130. Moreover, the condensed water storage section 150 may be connected to the heat exchange section 120 and the pipe 156 to supply the condensed water to the heat exchange section 120.

The heat transferred to the thermoelectric element 133 is transferred to the low-temperature part 132 and the low temperature part 132 is cooled by the fluid of the external environment supplied through the fan 136 or the pump (not shown).

As described above, during the normal operation of the nuclear power plant, the reactor cooling and power generation system 100 may be operated simultaneously with the nuclear power generation facility.

FIG. 1C is a conceptual view illustrating a forced circulation operation of the reactor cooling and power generation system 100 according to the embodiment of the present invention during a nuclear design basis accident.

Referring to FIG. 1C, it is a conceptual view of the operation of the reactor cooling and power generation system 100 when the operation of the small pump 153 and the power production section 130 is enabled during a nuclear design basis accident.

Specifically, when an accident occurs in a nuclear power plant due to various causes, the safety systems, such as the passive residual heat removal system, the passive safety injection system, and the passive containment cooling system, including the emergency cooling water storage section 20, which are installed in the plurality of trains, may be automatically operated in response to related signals. Further, steam generated by the operation of the safety system may be discharged from the steam discharge portion 25 of the emergency cooling water storage section 20.

The operation of the safety system may remove residual heat generated in the reactor coolant system 111 and the core 114. In addition, safety injection water may be supplied to the reactor coolant system 111 to lower pressure and temperature of the reactor coolant system 111 and lower the temperature of the core 114. Also, a pressure increase inside the reactor containment (not shown) may be suppressed by the operation of the passive containment cooling system, so as to protect the reactor containment.

On the other hand, while the isolation valves 12, 13 provided in the main feedwater line 11 and the main steam line 14 are closed, the operation of the large turbine 15 is stopped. However, even when the reactor core 114 is stopped, residual heat is generated in the core 114 for a considerable period of time, and a lot of sensible heat is present in the reactor coolant system 110 and the reactor vessel 110. As a result, the temperature of the reactor coolant system 111 does not decrease rapidly.

In other words, during a nuclear design basis accident, the nuclear power generation facility is stopped, but the reactor cooling and power generation system 100 continues to operate. Accordingly, emergency power supply and residual heat removal may be efficiently carried out.

Accordingly, even when an accident occurs, the heat exchange section 120 and the power production section 130 may be operated in a substantially similar state as a normal operation. Therefore, the power production section 130 may cool the reactor vessel 110 while continuously producing electric power. Over time, the temperature of the reactor vessel 110 may decrease as the residual heat generated in the core 114 decreases. In this case, as the heat transferred is reduced, the temperature difference and the electromotive device may be reduced and accordingly an amount of power produced by the power production section 130 may be decreased. The reactor cooling and power generation system 100 may thusly be operated almost similar to the normal operation.

FIG. 1D is a conceptual view illustrating a natural circulation operation of the reactor cooling and power generation system 100 according to the embodiment of the present invention during a nuclear design basis accident.

Referring to FIG. 1D, it is a conceptual view in which the operation of the small pump 153 is disabled due to a natural circulation operation during a design basis accident of the reactor cooling and power generation system 100. As in the foregoing case of FIG. 1C, the safety systems, such as the passive residual heat removal system, the passive safety injection system, and the passive containment cooling system, including the emergency cooling water storage section 20, which are installed in the plurality of trains, may be automatically operated in response to related signals. Accordingly, the reactor coolant system 111 is cooled, and the residual heat of the core 114 is removed, and safety injection water is supplied to the reactor coolant system 111 to reduce the pressure and temperature of the reactor coolant system 111, reduce the temperature of the core 114, and suppress a pressure increase inside the reactor containment (not shown) to protect the reactor containment. On the other hand, while the isolation valves 12, 13 provided in the main feedwater line 11 and the main steam line 14 are closed, the operation of the large turbine 15 is stopped.

In detail, when supply of feedwater from the small pump 153 is stopped for various reasons, the valve 157 and the check valve 158 connected to the condensed water storage section 150 may be opened by the related signal or the operator action, to supply feedwater from the condensed water storage section 150 through the pipe 159, and at this time, the feedwater may be supplied by natural circulation due to gravity.

In other words, the gravity acts on the condensed water in the condensed water storage section 150 to supply the condensed water by the natural circulation. Accordingly, the heat exchange section 120 and the power production section 130 may be operated in a state similar to that in the normal operation except for the small pump 153. As time elapses, when a steam generation amount is reduced due to a gradual reduction of the residual heat of the core 114, the operation state may become similar to that during the normal operation while reducing a power production amount of the power production section 130.

FIG. 1E is a conceptual view illustrating the operation of the reactor cooling and power generation system 100 according to the embodiment of the present invention during a severe accident of the nuclear power plant.

Referring to FIG. 1E, it is a conceptual view in which the operation of the reactor cooling and power generation system 100 is disabled due to a severe accident operation of the reactor cooling and power generation system 100. As in the foregoing cases of FIGS. 10 and 1D, the safety systems, such as the passive residual heat removal system, the passive safety injection system, and the passive containment cooling system, including the emergency cooling water storage section 20, which are installed in the plurality of trains, may be automatically operated in response to related signals. However, when it is assumed that various safety systems and non-safety systems do not operate although it is rarely likely to occur, an accident in which the core is melted down due to a temperature rise of the core may occur.

For example, in order to block the discharge of radioactive materials to the outside of the reactor containment during a severe accident such as a generation of corium 114′ of nuclear accidents, the operation of the heat exchange section 120 and the power production section 130 may be stopped. Accordingly, the pipe 173 connected to the IRWST 170 may be opened by the related signal or the operator action to receive refueling water from the IRWST 170. As a result, the refueling water may be used to cool a lower portion of the reactor vessel 110, the reactor coolant system 111 including the reactor vessel 110 and the corium.

In addition, since a flow path through the IRWST 170 and the second discharge section 175 is already formed, the supply and discharge of the refueling water, namely, cooling water supplied from the IRWST 170 may be efficiently carried out by a simple operation such as opening and closing the valve or the like according to an operator action. In detail, the second discharge portion 175 may discharge the refueling water received from the IRWST 170 (i.e., a fluid (gas/steam, a mixture of gas/steam and liquid/hot water or liquid/hot water) into the reactor containment (not shown).

Furthermore, even when a severe accident such as damage to the reactor vessel or exposure of the reactor core 114 occurs of nuclear accidents, in addition to the generation of the corium 114′ in the reactor, the operation of the heat exchange section 120 and the power production section 130 may be stopped to allow the injection of feedwater through the IRWST 170 and the opening of a valve 127′ connected to the first discharge portion 127 in terms of protection.

Besides, the pipe 173 connected to the IRWST 170 may be configured to cool the reactor vessel 110 and the reactor coolant system even when cooling and power generation using the heat exchange section 120 and the power production section 130 are disabled due to a failure thereof.

Depending on the characteristics of the nuclear power plant, a pump (not shown) may be installed in the pipe 173 connected to the IRWST 170 to forcibly inject feedwater or inject feedwater using gravity.

Furthermore, according to another embodiment described below, the same or similar reference numerals are designated to the same or similar configurations to the foregoing example, and the description thereof will be substituted by the earlier description.

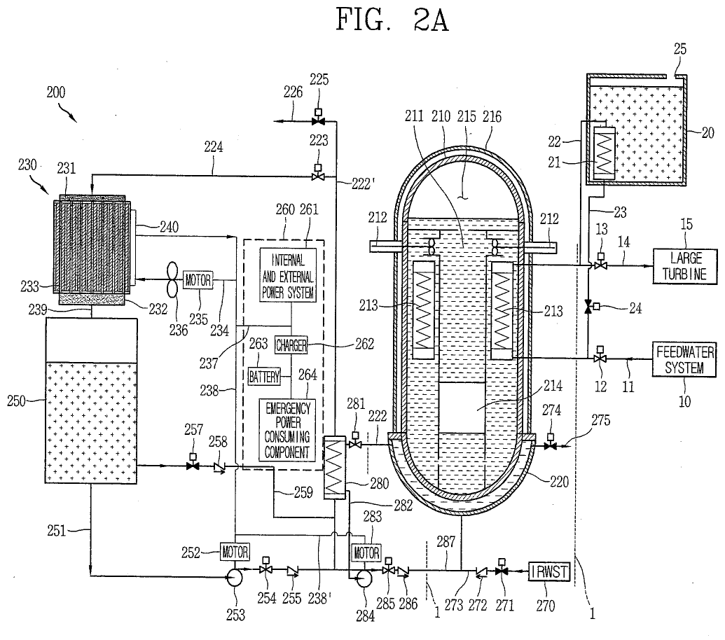

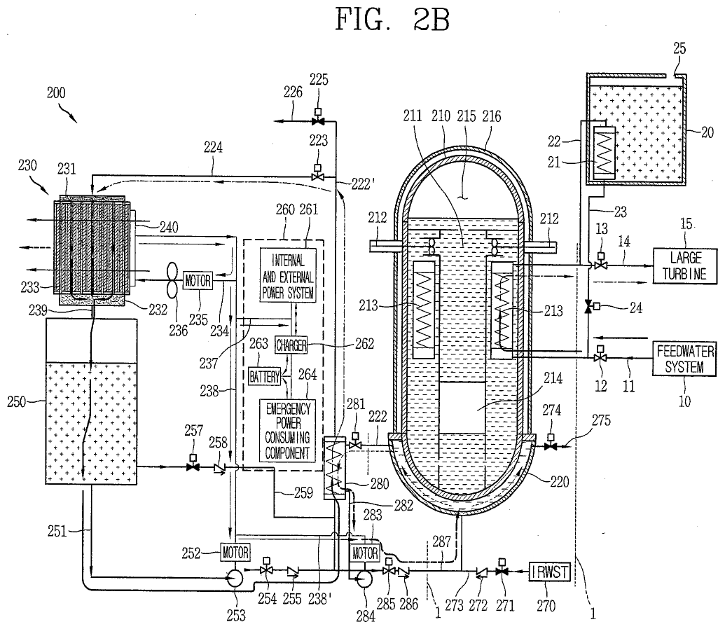

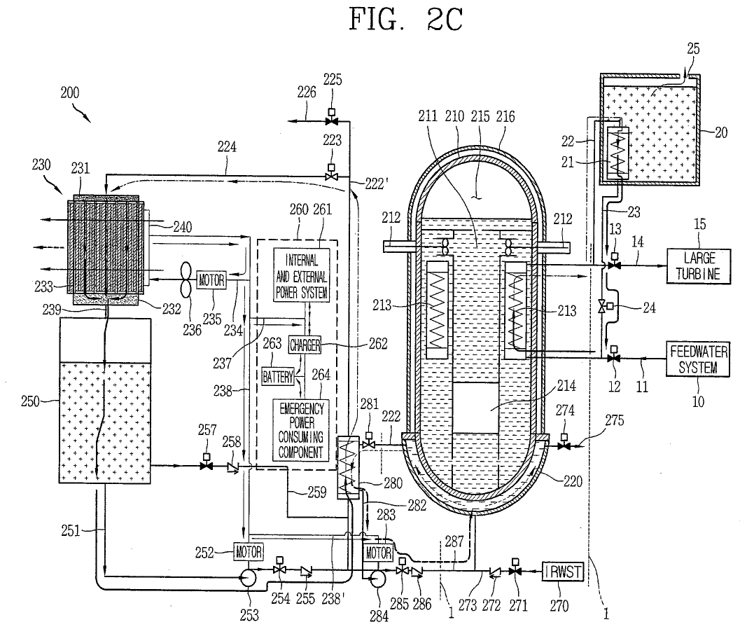

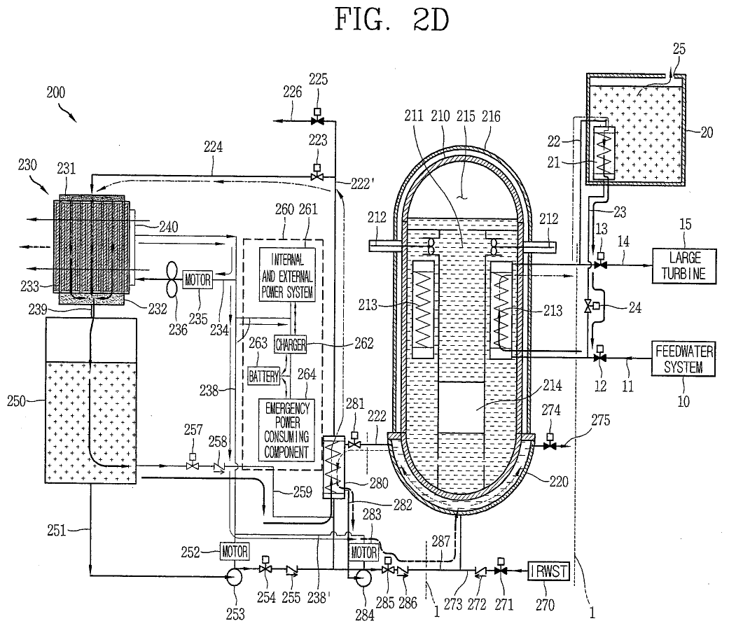

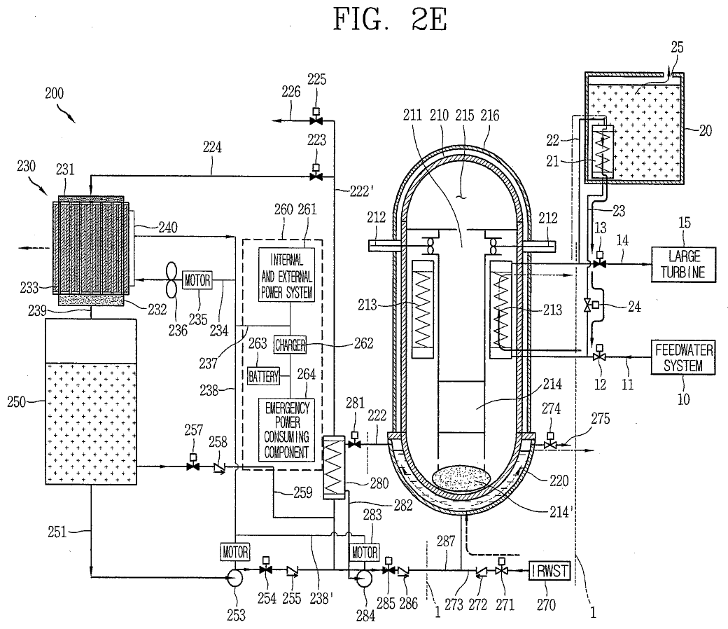

FIG. 2A is a conceptual view of a reactor cooling and power generation system 200 in accordance with another embodiment of the present invention.

Referring to FIG. 2A, the reactor cooling and power generation system 200 may further include an evaporation section 280 connected to a heat exchange section 220, and the evaporation section 280 may be configured to perform heat exchange between an internal fluid of the heat exchange section 220 and condensed water of a condensed water storage section 250.

In detail, a first circulation part may be formed from the heat exchange section 220 to the evaporation section 280 such that a fluid flows therealong. On the other hand, a second circulation part may be formed sequentially along the evaporation section 280, the power production section 230, and the condensed water storage section 250 such that the fluid flows therealong.

That is, the reactor cooling and power generation system 200 may have dual circulation loop including the first circulation part and the second circulation part. The evaporation section 280 may be a boundary between the first circulation part and the second circulation part. The first circulation part may be formed such that a single-phase fluid circulates therealong. In detail, the single-phase fluid of the first circulation part may be compressed gas (gas).

The fluid circulating through the first circulation part exchanges heat with the evaporation section 280 through a discharge pipe 222 and a valve 281 connected to the heat exchange section 220. The fluid being heat-exchanged in the evaporation section 280 may be supplied to the heat exchange section 220 through a pipe 282, a compressor 284, a valve 285, a check valve 286 and a pipe 287. In detail, the compressor 284 or a blower (not shown) may be formed to perform the circulation of the single-phase fluid of the first circulation part. A motor 283 that operates the compressor 284 may receive electric power by a connection line 238′ branched from a connection line 238.

On the other hand, the fluid circulating through the second circulation part may be supplied from a small pump 253 to the evaporation section 280 through a valve 254, a check valve 255 and a pipe 256. A fluid converted into steam in the evaporation section 280 may be supplied to the power production section 230 through the discharge pipe 222′ and then cooled, condensed, stored in the condensed water storage section 250, so as to circulate through the pipe 251.

In other words, the fluid circulating through the second circulation part may be supplied to the power production section 230 including the thermoelectric element 233 while circulating through the second circulation part described above. Accordingly, thermal energy of the fluid may be transferred to the thermoelectric element 233 to generate an electromotive force. The electromotive force may be collected to produce power. Moreover, the power produced by the power production section 230 may be used as power of a power system 260.

The heat exchange section 220 capable of cooing the outer wall of the reactor vessel 210 may be formed in a hemispherical shape as illustrated in the drawing, and the heat exchange section 220 may cool the outer wall of the reactor vessel 210 without a coating member or a heat transfer enhancement member.

According to this embodiment, there is a disadvantage in that the evaporation section 280 is further employed compared to the embodiment of FIG. 1A, but it has an effect of physically separating a fluid circulating through the first circulation part and a fluid circulating through the second circulation part, and there is an advantage of cooling the reactor vessel 210 using a single-phase fluid.

FIG. 2B is a conceptual view illustrating the operation of the reactor cooling and power generation system 200 according to the another embodiment of the present invention during a normal operation of the nuclear power plant.

Referring to FIG. 2B, it is a conceptual view illustrating system arrangement and a fluid flow during a normal operation of the nuclear power plant. During a normal operation of a nuclear power plant, main feedwater (water) is supplied from the feedwater system 10 to a steam generator 213, and heat received from a core 214 by the reactor coolant circulation is transferred to a secondary system through the steam generator 213 to increase a temperature of the main feedwater and produce steam. The steam produced from the steam generator 213 is supplied to the large turbine 15 along the main steam line 14 to operate the large turbine 150 and rotate the large generator (not shown) connected through the shaft to produce electric power. The power produced through the large generator may be supplied to an on-site or off-site from the power system.

On the other hand, the single-phase fluid inside the heat exchange section 220 having a shape capable of cooling the outer wall of the reactor vessel 210 receives heat of the outer wall of the reactor vessel 210 and flows to the evaporation section 280. The single-phase fluid moved to the evaporation section 280 transfers heat to a fluid to be supplied to the high-temperature part 231 of the power production section 230. That is, the single-phase fluid circulates through the heat exchange section 220 and the evaporation section 280 so as to form the circulation of the first circulation part. Moreover, the compressor 284 and the blower (not shown) connected to the motor 283 may be configured to efficiently perform the circulation of the single-phase fluid circulating through the first circulation part.

On the other hand, the fluid supplied from the small pump 253 to the evaporation section 280 through the valve 254, the check valve 255 and the pipe 256 may be supplied to the power production section 230 including the thermoelectric element 233 while circulating through the second circulation part, and the thermal energy of the fluid may be converted into mechanical energy through the thermoelectric element 233 so as to generate power. Moreover, the power produced by the power production section 230 may be used by the power system 260.

FIG. 2C is a conceptual view illustrating a forced circulation operation of the reactor cooling and power generation system 200 according to the embodiment of the present invention during a nuclear design basis accident.

Referring to FIG. 2C, it is a conceptual view of the operation of the reactor cooling and power generation system 200 when the operation of the small pump 253 and the power production section 230 is enabled during a nuclear design basis accident.

Specifically, when an accident occurs in a nuclear power plant due to various causes, the safety systems, such as the passive residual heat removal system, the passive safety injection system, and the passive containment cooling system, including the emergency cooling water storage section 20, which are installed in the plurality of trains, may be automatically operated in response to related signals. Further, steam generated by the operation of the safety system may be discharged from the steam discharge portion 25 of the emergency cooling water storage section 20.

The operation of the safety system may remove residual heat generated in the reactor coolant system and the core 214. In addition, safety injection water may be supplied to the reactor coolant system to lower pressure and temperature of the reactor coolant system and lower temperature of the core 214. Also, a pressure increase in the reactor containment (not shown) may be suppressed by the operation of the passive containment cooling system so as to protect the reactor containment.

On the other hand, while the isolation valves 12, 13 provided in the main feedwater line 11 and the main steam line 14 are closed, the operation of the large turbine 15 is stopped. However, since the temperature of the reactor vessel 210 at an initial stage of the accident is similar to a normal operation condition of the nuclear power plant, the heat exchange section 220 and the power production section 230 respectively connected to the evaporator section 280 may be operated in a substantially similar state as the normal operation.

As time elapses, when the temperature of the reactor vessel 210 decreases in response residual heat generated in the core 214 being reduced and the reactor vessel 210 being cooled by the safety system, a power production amount of the power production section 230 may be reduced according to an amount of transferred heat and thus the power production section 230 may operate similar to the normal operation.

FIG. 2D is a conceptual view illustrating a natural circulation operation of the reactor cooling and power generation system 200 according to the embodiment of the present invention during a nuclear design basis accident.

Referring to FIG. 2D, it is a conceptual view in case where the operation of the small pump 253 is disabled due to a natural circulation operation during a design basis accident of the reactor cooling and power generation system 200. As in the foregoing case of FIG. 2c, the safety systems, such as the passive residual heat removal system, the passive safety injection system, and the passive containment cooling system, including the emergency cooling water storage section 20, which are installed in the plurality of trains, may be automatically operated in response to relative signals. Accordingly, the reactor coolant system may be cooled, the residual heat of the core 214 may be removed and safety injection water may be supplied to the reactor coolant system 211 so as to lower pressure and temperature of the reactor coolant system and lower the temperature of the core 214. Also, a pressure increase in the reactor containment (not shown) may be suppressed so as to protect the reactor containment. On the other hand, while the isolation valves 12, 13 provided in the main feedwater line 11 and the main steam line 14 are closed, the operation of the large turbine 15 is stopped.

In detail, when supply of feedwater from the small pump 253 is stopped for various reasons, the valve 257 and the check valve 258 connected to the condensed water storage section 250 may be opened by the related signal or the operator action, to supply feedwater from the condensed water storage section 250 to the evaporation section 280 through the pipe 259, and at this time, the feedwater may be supplied by natural circulation due to gravity.

In other words, the gravity acts on the condensed water in the condensed water storage section 250 to supply the condensed water by the natural circulation. Accordingly, the heat exchange section 220 and the power production section 230 may be operated in a state similar to that in the normal operation except for the small pump 253. As time elapses, when a steam generation amount is reduced due to a gradual reduction of the residual heat of the core 214, the operation state may become similar to that during the normal operation while reducing a power production amount of the power production section 230.

FIG. 2E is a conceptual view illustrating the operation of the reactor cooling and power generation system 200 according to the embodiment of the present invention during a severe accident of the nuclear power plant.

Referring to FIG. 2E, it is a conceptual view of the operation of the reactor cooling and power generation system 200 when the operation of the reactor cooling and power generation system 200 is stopped during a severe nuclear accident. As in the foregoing case of FIG. 2C, the safety systems, such as the passive residual heat removal system, the passive safety injection system, and the passive containment cooling system, including the emergency cooling water storage section 20, which are installed in the plurality of trains, may be automatically operated in response to relative signals. However, when it is assumed that various safety systems and non-safety systems do not operate although it is rarely likely to occur, an accident in which the core is melted down due to a temperature rise of the core may occur.

For example, when a severe accident such as the generation of corium 214′ occurs of nuclear accidents, the heat exchange section 220 and the power production section 230, which are respectively connected to the evaporation section 280, may be interrupted. As a result, the valve 271 and the check valve 272 connected to the IRWST 270 may be opened by the related signal or the operator action to supply feedwater from the IRWST 270 through the pipe 273 so as to cool a lower portion of the reactor vessel 210, and the valve 274 provided in the second discharge portion 275 may be opened to discharge the generated steam. Depending on characteristics of nuclear power plants, the feedwater may be forcibly injected by installing a pump (not shown) in the pipe 273 connected to the IRWST 270 or may be injected using gravity.

Furthermore, even in case where a severe accident such as damage to the reactor vessel or exposure of the reactor core 214 has occurred of nuclear accidents, in addition to the generation of the corium 214′ in the reactor, when the operation of the heat exchange section 220 and the power production section 230 respectively connected to the evaporation section 280 is stopped, the injection of feedwater through the IRWST 270 and the opening of the valve 274 connected to the second discharge portion 127 may be enabled in terms of protection.

Furthermore, according to another embodiment described below, the same or similar reference numerals are designated to the same or similar configurations to the foregoing example, and the description thereof will be substituted by the earlier description.

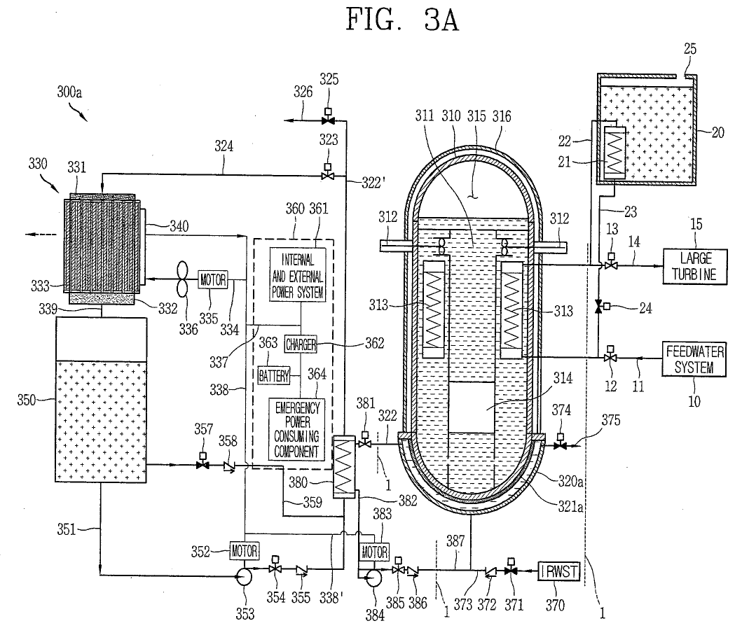

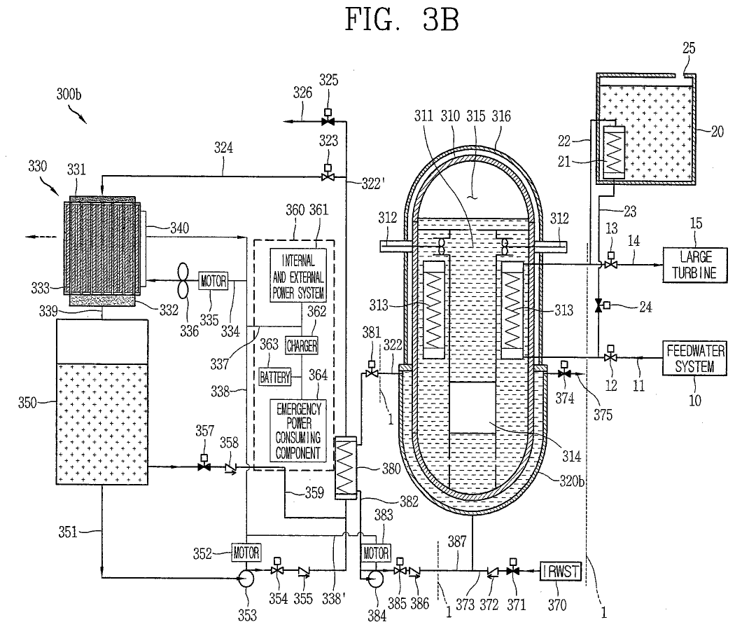

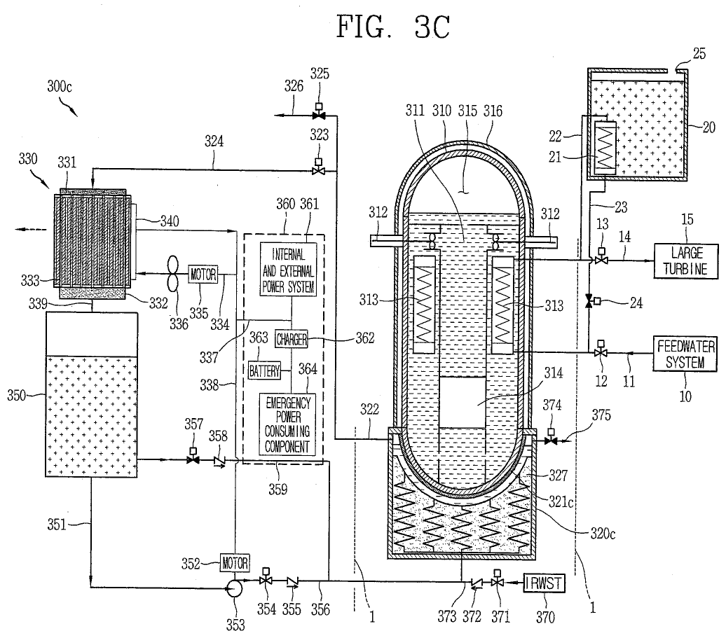

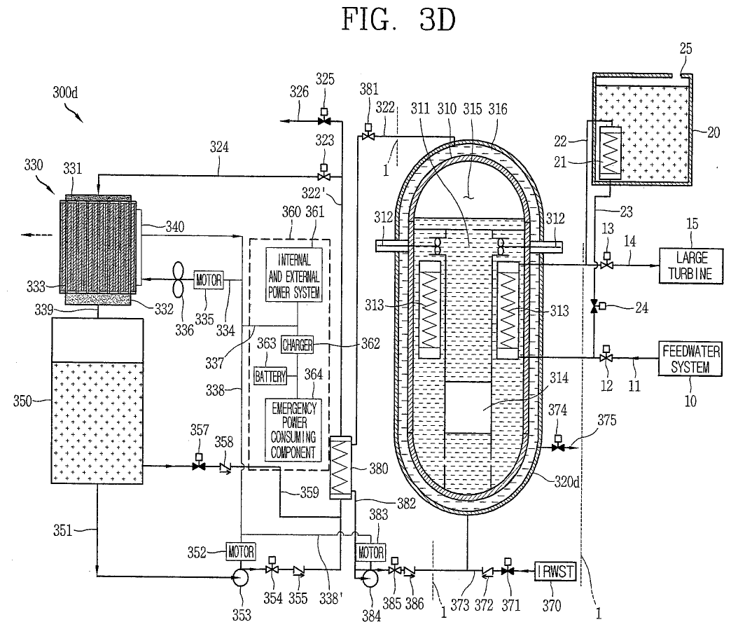

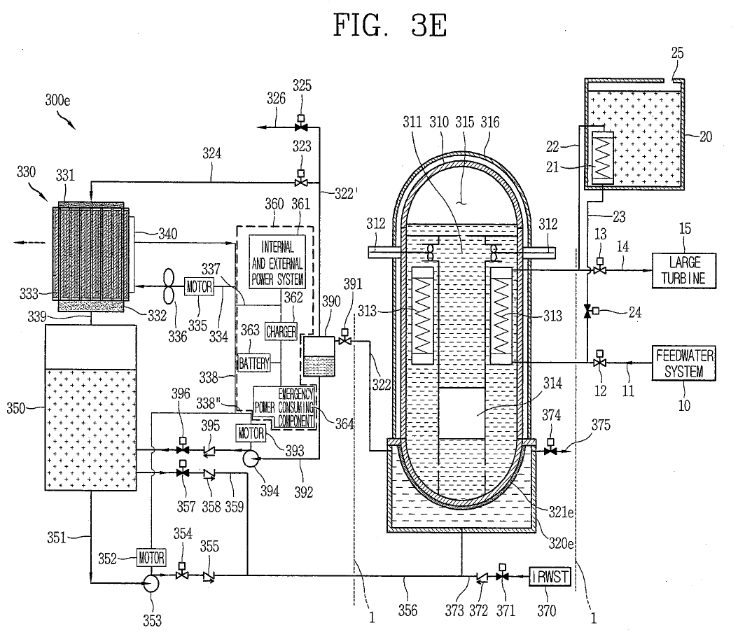

FIGS. 3A to 3E are conceptual views of a reactor cooling and power generation system according to still another embodiment of the present invention.

Referring to FIG. 3A, a heat exchange section 320a of a reactor cooling and power generation system 300a may have a hemispherical shape. In addition, the heat exchange section 320a having a shape capable of cooling the outer wall of the reactor vessel may further include a coating member 321a for preventing corrosion or increasing heat transfer efficiency. In an embodiment, a surface of the coating member 321a may be reformed in various ways and may also be processed into an uneven shape (cooling fin) to increase the heat transfer surface area. Further, the coating member 321a may further include a heat transfer member (not shown) whose surface is chemically processed to increase a surface area so as to improve heat transfer efficiency. That is, the surfaces of the coating member 321a and the heat transfer member may be chemically processed to increase the surface areas thereof, such that the heat transfer can be efficiently carried out.

In addition, the reactor cooling and power generation system 300a may further include an evaporation section 380 connected to the heat exchange section 320a in a similar manner to the heat exchange section 220 of FIG. 2A. The evaporation section 380 may be configured such that a fluid inside the heat exchange section 320a exchanges heat with condensed water of a condensed water storage section 350. That is, the reactor cooling and power generation system 300a may be formed to have a dual circulation loop of a first circulation part and a second circulation part.

Referring to FIG. 3B, a heat exchange section 320b of a reactor cooling and power generation system 300b may have a mixed shape of a hemispherical shape and a cylindrical shape. Various shapes may be employed to increase a heat transfer area of the heat exchange section 320b. Furthermore, the heat exchange section 320b may also cool the outer wall of the reactor vessel 310 without a coating member or a heat transfer enhancement member.

Referring to FIG. 3C, a reactor cooling and power generation system 300c may further include a core catcher 327 inside a heat exchange section 320c having a shape capable of cooling the outer wall of the reactor vessel 310, and the core catcher 327 may be configured to receive and cool corium when the reactor vessel 310 is damaged. In addition, the heat exchange section 320c may further include a coating member 321c for preventing corrosion or increasing heat transfer efficiency.

Referring to FIG. 3D, in a reactor cooling and power generation system 300d, a heat exchange section 320d which is configured to cool the outer wall of the reactor vessel may have a dual vessel form so as to enclose the entire reactor vessel 310. Various shapes may be employed to increase a heat transfer area of the heat exchange section 320d.

Referring to FIG. 3E, a reactor cooling and power generation system 300e may further include a gas-fluid separator 390 formed to mount a valve 391 connected to the discharge pipe 322 thereof, and the gas-fluid separator 390 may be configured to transfer only gas in a fluid circulating inside the heat exchange section 320e to the power production section 330 through the discharge pipe 322′. Further, the system 300e may further include a cooling water recovery pipe 392 and a pump 394 by which a liquid separated from the gas-fluid separator 390 is recovered into the condensed water storage section 350.

A motor 393 that operates the compressor 394 may receive electric power by a connection line 338″ branched from a connection line 338. A liquid separated from the gas-fluid separator 390 may be recovered to the condensed water storage section 350 through a cooling water recovery pipe 392, a pump 394, a check valve 395 and a valve 396. Specifically, it may be designed and operated at pressure higher than a vaporization point of a liquid to induce a single-phase liquid circulation from the pump 394 to the gas-water separator 390, and the liquid and the gas may be separated by the gas-fluid separator 390.

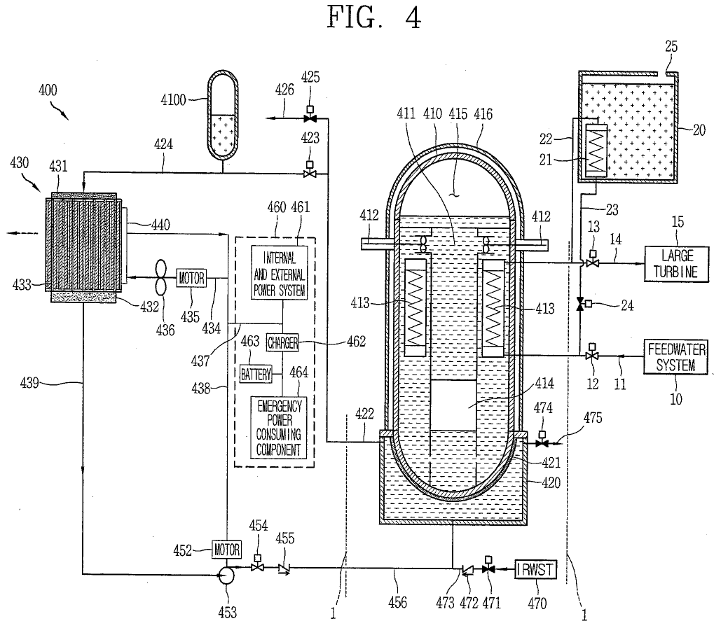

FIG. 4 is a conceptual view of a reactor cooling and power generation system 400 according to still another embodiment of the present invention.

Referring to FIG. 4, a reactor cooling and power generation system 400 may be configured such that a fluid inside a heat exchange section 420 circulates in a single-phase liquid state through a power production section 430.

In case where the fluid circulating through the reactor cooling and power generation system 400 is a single-phase liquid, pressure of a circulation loop may be rapidly increased when the volume changes according to temperature, and therefore, a pressure control section 4100 may be provided to absorb a change in volume of the single-phase liquid, and control the pressure.

On the other hand, when the fluid circulating through the reactor cooling and power generation system 400 is a single-phase liquid (liquid-phase fluid), heat transfer efficiency may increase as compared with a case where high-pressure gas (gas-phase fluid) circulates.

Furthermore, when the pressure control section 4100 is used to pressurize the liquid at preset pressure, the requirement of a net positive suction head (NPSH) of the small pump 453 may be relaxed. In addition, when the fluid circulating through the reactor cooling and power generation system 400 is a single-phase liquid, the condensed water storage section and pipes and valves associated with the condensed water storage section may be removed to construct the reactor cooling and power generation system 400 in a simplified manner. In other words, the circulation of the fluid in the reactor cooling and power generation system 400 may be simplified. Also, as the pipe and the circulation loop are simplified, the application of safety grade or seismic design may be facilitated.

FIGS. 5A to 5C are conceptual views of a reactor cooling and power generation system according to yet still another embodiment of the present invention.

Hereinafter, description will be given in more detail of a reactor cooling and power generation system provided with a heat exchange section 520 disposed inside a reactor vessel to operate even during an accident as well as during a normal operation of the nuclear power plant so as to generate electric power, with reference to FIGS. 5A to 5C.

Referring to FIG. 5A, a heat exchange section 520 of a reactor cooling and power generation system 500a may be provided inside a reactor vessel 510 to receive heat from a reactor coolant system 511 inside the reactor vessel 510. In detail, the heat exchange section 520 may be configured to circulate a fluid, which can receive heat from the reactor coolant system 511, to perform cooling the inside of the reactor vessel 510.

In other words, the heat exchange section 520 may cool a reactor coolant inside the reactor vessel 510 during a normal operation of the nuclear power plant. The heat exchange section 520 may also cool the reactor coolant and corium during an accident of the nuclear power plant.

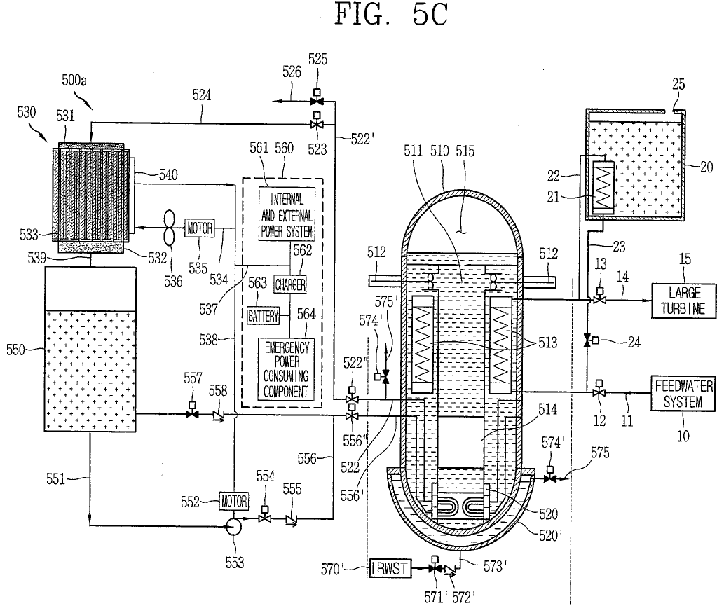

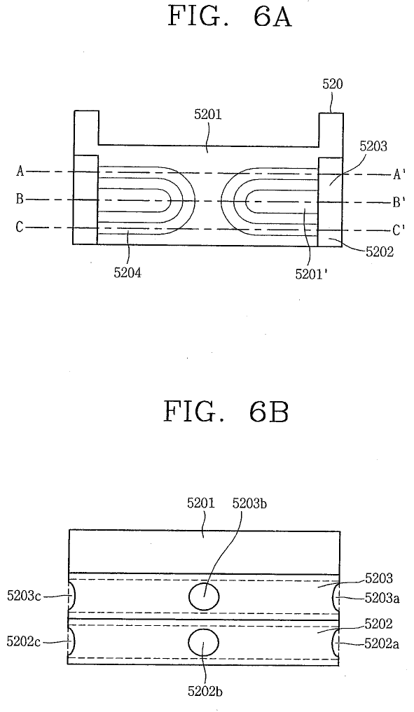

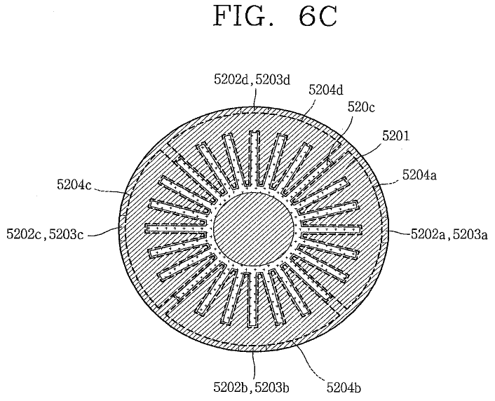

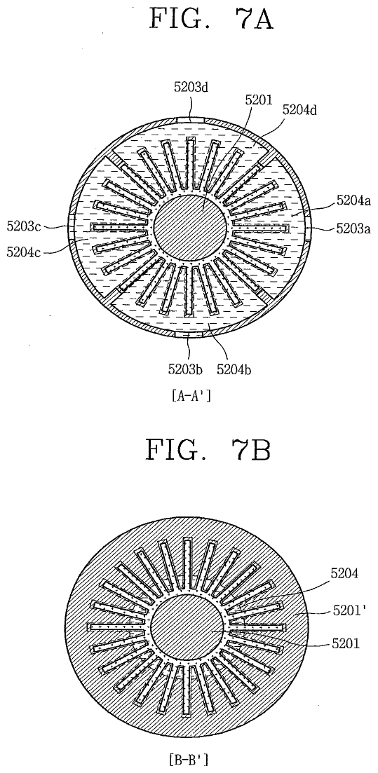

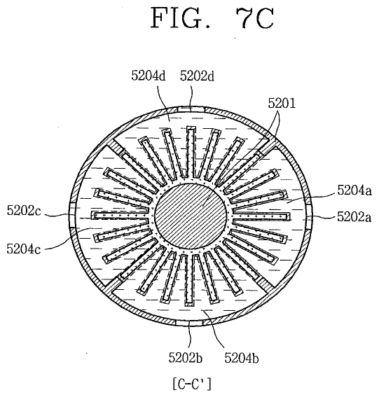

Referring to the layout of detailed structures of the heat exchange section 520, the heat exchange section 520 may include an inlet header having inlets through which the fluid is introduced, an outlet header having outlets through which the fluid is discharged, and an inner flow path in which the fluid exchanges heat. Furthermore, a core catcher may be provided as an additional structure of the heat exchange section 520 to receive and cool the corium of a core 514 during a severe accident. Detailed description of the heat exchange section 520 will be described later with reference to FIGS. 6A to 6C and 7A to 7C.

In addition, the fluid in the heat exchange section 520 may pass through a discharge pipe 522, a valve 522″ and a discharge pipe 522′, and the discharge pipe 522′ may be branched to a pipe 524 passing through a valve 523. As a result, the fluid in the heat exchange section may be supplied to a power production section 530.

The fluid supplied to the power production section 530 may perform power production by use of a thermoelectric element 533 through heat exchange. Moreover, the heat-exchanged and discharged fluid is condensed and transferred to a condensed water storage section 550 along a pipe 539.

The condensed water as a condensed fluid collected in the condensed water storage section 550 may circulate through the heat exchange section 520 and the power production section 530. Moreover, the condensed water storage section 550 may be provided with pipes 556 and 556′ connected to the heat exchange section 520 through a valve 556″ to supply the condensed water to the heat exchange section 520.

Specifically, the condensed water in the condensed water storage section 550 may also flow through a valve 554 and a check valve 555 by a motor 552 and a small pump 553 connected to a pipe 551 to be supplied into the pipes 556, 556′ connected to the heat exchange section 520. Furthermore, the condensed water may be supplied to the pipe 556′ connected to the heat exchange section 520 by gravity through a valve 557 and a check valve 558 connected to the pipe 539 of the condensed water storage section 550.

The discharge pipe 522′ may further include a first discharge portion 526 connected to a valve 525, and the first discharge portion 526 may be configured to discharge at least part of the fluid excessively supplied to the power production section 530 or bypass the at least part of the fluid to the power production section 530.

Moreover, the heat exchange section 520 may be connected to an IRWST 570 through a pipe 573 such that refueling water can be supplied. In detail, the IRWST 570 may be connected to a valve 571 and a check valve 572. As a result, a second discharge portion 575 connected to a valve 574 may be provided to discharge the refueling water supplied from the IRWST 570 through the pipe 573 and the pipe 556′ during an accident.

In detail, the second discharge portion 575 is a pipe through which a fluid (gas/steam, a mixture of gas/steam and liquid/hot water, or liquid/hot water) is discharged from the heat exchange section 520 into the reactor containment (not shown). Accordingly, the second discharge portion 127 can allow the reactor vessel to be cooled even when the heat exchange section 520 and the power production section 530 are unable to perform cooling and electric power generation due to their failure or the like caused by a severe accident and the like.

Referring to FIG. 5B, a reactor cooling and power generation system 500b may be configured such that the fluid in the heat exchange section 520 circulates in a single-phase liquid state through the power production section 530. As a result, similarly to FIG. 4, a pressure control section 5100 may be provided to control pressure of the single-phase liquid.

In addition, when the fluid circulating through the reactor cooling and power generation system 500b is a single-phase liquid, the foregoing condensed water storage section and pipes and valves associated with the condensed water storage section may be removed to construct the reactor cooling and power generation system 500b in a simplified manner.

Referring to FIG. 5C, a reactor cooling and power generation system 500c may further include a heat exchange section 520′ having a shape capable of cooling the outer wall of the reactor vessel 510. The heat exchange section 520′ may be formed to enclose the reactor vessel 510 and receive heat discharged from the reactor vessel 510 so as to cool the outer wall of the reactor vessel 510.

In detail, the shape of the heat exchange section 520′ may be hemispherical. However, the shape of the heat exchange section 520′ is not limited to a cylindrical shape, and at least a part of the shape of the heat exchange section 520′ may include a cylindrical shape, a hemispherical shape, a double vessel shape or a mixed shape thereof.

In addition, the heat exchange section 520c′ may further include a coating member (not shown) for preventing corrosion or increasing heat transfer efficiency. The surface of the coating member may be reformed in various ways and may also be processed in an uneven shape (cooling fin) to increase the heat transfer surface area. Further, the surface of the coating member may further include a heat transfer member (not shown) that can be chemically processed to increase the surface area so as to improve heat transfer efficiency.

Besides, the heat exchange section 520′ may be connected to the IRWST 570′ through the pipe 573′ such that refueling water can be supplied. Specifically, the heat exchange section 520′ may be connected to a valve 571′ and a check valve 572′. Moreover, when a severe accident occurs, the heat exchange section 520′ may further include a discharge portion 575′ connected to a valve 574′ to discharge the refueling water, which is supplied from the IRWST 570′ through the pipe 573′.

FIGS. 6A to 6C are views illustrating in detail the heat exchange section 520 of FIGS. 5A to 5C.

FIG. 6A is an enlarged view of the conceptual view of the heat exchange section 520.

FIG. 6B is a side view of the heat exchange section 520. In addition, FIG. 6C is a top view of the heat exchange section 520.

Referring to FIGS. 6A to 6C, the heat exchange section 520 may include an inlet header 5202, an outlet header 5203, an inner flow path 5204, and structures 5201, 5201′ for forming the inner flow path 5204, and may also be provided with a core catcher including a corium flow path 520c for receiving and cooling corium during a severe accident.

In detail, the heat exchange section 520 arranges inlets 5202a, 5202b, 5202c, 5202d in the inlet header 5202 to inject a fluid (a fluid during a normal operation, IRWST refueling water during a severe accident) into the inner flow path 5204. In addition, the inner flow path 5204 may be formed in a U-like shape so as to surround the structure 5201′ so that the fluid of low temperature receives heat while rotating around the structure 5201′ so as to be increased in temperature. Further, the fluid having the temperature increased while passing through the inner flow path 5204 may be discharged to outlets 5203a, 5203b, 5203c, 5203d of the outlet header 5203.

In detail, as illustrated in FIG. 6C, the heat exchange section 520 may be configured such that the fluid flows into the inlet 5202a and is discharged to the outlet 5203a through the flow path 5204a. In addition, the inlets 5202a to 5202d may be formed to correspond to flow paths 5204a to 5204d and the outlets 5203a to 5203d, respectively.

The corium generated due to a meltdown of the core during a severe accident may be cooled by the fluid (IRWST refueling water) while spreading radially from a central portion to an edge of the heat exchange section 520 along the corium flow path 520c.

FIGS. 7A to 7C are sectional views taken along lines A-A′, B-B′ and C-C′, respectively, of the heat exchange section 520 of FIG. 6A.

Specifically, FIG. 7A is a top sectional view of the heat exchange section 520 cut along the line A-A′ of FIG. 6A. Referring to FIG. 7A, the fluid having the temperature increased while passing through the flow paths 5204a to 5204d of the heat exchange section 520 cut along the line A-A′ may be discharged to the outlets 5203a, 5203b, 5203c, 5203d.

Furthermore, FIG. 7B is a middle sectional view of the heat exchange section 520 cut along the line B-B′ of FIG. 6A. Referring to FIG. 7B, the heat exchange section 520 is configured such that a fluid (a fluid during a normal operation, IRWST refueling water during a severe accident) flows from a bottom to a top through the inner flow path 5204 of the heat exchange section 520 cut along the line B-B′, and the fluid receives heat while flowing upward so as to be increased in temperature.

Moreover, FIG. 7C is a bottom sectional view of the heat exchange section 520 cut along the line C-C′ of FIG. 6A. Referring to FIG. 7C, the heat exchange section 520 may be configured such that the fluid of low temperature flows into the inlets 5202a, 5202b, 5202c, 5202d of the heat exchange section 520 cut along the line C-C′, and passes through the flow paths 5204a to 5204d to be discharged to the outlets 5203a, 5203b, 5203c, 5203d at the upper portion of the heat exchange section 120. In addition, since the heat exchange section 520 can also be configured in various similar forms, the present invention is not limited to the form of this embodiment.

FIG. 8 is a conceptual view illustrating a detailed structure of a thermoelectric element applied to a reactor cooling and power generation system according to the present invention.

Referring to FIG. 8, a high-temperature part 8031 may be provided which has a shape of a flow path along which a fluid of high temperature receiving heat from a heat exchange section flows. And a low-temperature part 8032 may be provided which has a shape of a flow path along which a fluid of low temperature flows. In detail, the thermoelectric element may be a type of a heat exchanger in which heat exchange can be performed between the high-temperature part 8031 and the low-temperature part 8032. The heat exchanger may be a plate type heat exchanger, but the present invention is not limited to the type of the heat exchanger but may also employ a type of heat exchanger in which the heat exchange between the high-temperature part 8031 and the low-temperature part 8032 can be smoothly performed.

The low-temperature part 8032 may dissipate heat transferred from the high-temperature part 8031 through the thermoelectric element 8033 by using a fluid (air, fresh water or seawater) of an external environment which is lower in temperature than a fluid supplied to the high-temperature part 8031.

Also, an electromotive force may be generated as a temperature difference between the high-temperature part 8031 and the low-temperature part 8032 is transferred to a semiconductor 8033a. The thermoelectric element 8033 may include a power production part 8040 configured to form a closed circuit of P-type and N-type semiconductors 8033a to produce power using the Seebeck effect. The power production part 8040 may be connected to a plurality of semiconductors, so as to produce more power.

In detail, the thermoelectric element 8033 may include a thermoelectric plate 8033b, and semiconductors 8033a and 8033c generating an electromotive force. Also, the thermoelectric element 8033 includes the power production part 8040 producing power, and an electric flow path 8041 connecting the semiconductors 8033c and the power production part 8040.

The thermoelectric plates 8033b are in contact with the high-temperature part 8031 or the low-temperature part 8032, and the semiconductors 8033a are disposed between the thermoelectric plates 8033b arranged on both sides. The semiconductors 8033a may be classified into P-type and N-type semiconductors, and the P-type and N-type semiconductors are alternately arranged at spaced distances. Further, the P-type and N-type semiconductors may be connected to each other through the thermoelectric plates 8033b.

A coating member may be further provided on a surface of the high-temperature part 8031 or the low-temperature part 8032 to prevent corrosion of the high-temperature part 8031 or the low-temperature part 8032. Further, a heat transfer member may also be provided on the surface of the high-temperature part 8031 or the low-temperature part 8032. The heat transfer member may be chemically processed to increase a surface area so as to improve heat transfer efficiency. In one embodiment, the heat transfer member may be radiation fins 8033d provided to increase the heat transfer efficiency.

Although the reactor cooling and power generation system according to various embodiments of the present invention has been described, but the present invention may not be limited to the foregoing reactor cooling and power generation system and may include a nuclear power plant having the same.

In detail, a nuclear power plant of the present invention may include a reactor vessel, a heat exchange section to receive heat generated from a core inside the reactor vessel through a fluid, and an power production section including a thermoelectric element formed to produce electric energy using energy of the fluid whose temperature has increased while receiving the heat of the reactor, and may be configured to circulate the fluid, which has received the heat from the core, through the power production section, and to operate even during an accident as well as during a normal operation to produce electric power.

It is obvious to those skilled in the art that the present invention can be embodied in other specific forms without departing from the concept and essential characteristics thereof.

Besides, the detailed description thereof should not be construed as restrictive in all aspects but considered as illustrative. The scope of the invention should be determined by reasonable interpretation of the appended claims and all changes that come within the equivalent scope of the invention are included in the scope of the invention.

1. A reactor cooling and electric power generation system, comprising:
a reactor vessel;
a heat exchange section to receive heat generated from a core inside the reactor vessel through a fluid; and
a power production section having a thermoelectric element configured to produce electric energy using energy of the fluid whose temperature has increased while receiving the heat of the reactor,
wherein the system is configured to allow the fluid that has received the heat from the core to circulate through the power production section, and
wherein the system operates even during an accident as well as during a normal operation of a nuclear power plant to produce electric power.

2. The system of claim 1, wherein the electric power produced during the normal operation of the nuclear power plant is supplied to an internal/external electric power system and an emergency battery.

3. The system of claim 2, wherein the electric energy charged in the emergency battery is formed to supply an emergency electric power as an emergency power source during a nuclear accident.

4. The system of claim 1, wherein the electric power produced during the accident of the nuclear power plant is supplied to an emergency power source of the nuclear power plant.

5. The system of claim 3, wherein the emergency power source is supplied as electric power for operating a safety system of the nuclear power plant during the accident of the nuclear power plant, opening and closing a valve for the operation of the safety system, monitoring the safety system, or operating the reactor cooling and electric power generation system.

6. The system of claim 1, wherein seismic design of seismic categories I, II or Ill is applied.

7. The system of claim 1, wherein safety classes 1, 2 or 3 are applied.

8. The system of claim 1, wherein a first discharge portion is provided to be connected to the heat exchange section, and
wherein the first discharge portion is formed such that at least part of the fluid excessively supplied to the power production section bypasses the power production section.

9. The system of claim 1, wherein the heat exchange section is provided to enclose at least part of the reactor vessel, and
wherein the heat exchange section is a heat exchange section having a shape of cooling an outer wall of the reactor vessel by receiving heat discharged from the reactor vessel which has received the heat generated from the core.

10. The system of claim 9, wherein at least part of the heat exchange section having the shape of cooling the outer wall of the reactor vessel has a cylindrical shape, a hemispherical shape, a double vessel shape, or a mixed shape thereof.

11. The system of claim 9, wherein the heat exchange section having the shape of cooling the outer wall of the reactor vessel is connected to an in-containment refueling water storage tank (IRWST) such that refueling water is supplied thereto.

12. The system of claim 11, wherein the heat exchange section having the shape of cooling the outer wall of the reactor vessel is provided with a second discharge portion, and
wherein the second discharge portion is formed to discharge the refueling water supplied from the in-containment refueling water storage tank (IRWST).

13. The system of claim 9, wherein the heat exchange section having the shape of cooling the outer wall of the reactor vessel is further provided with a coating member to prevent corrosion of the reactor vessel.

14. The system of claim 13, wherein a surface of the coating member is chemically processed to increase a surface area thereof.

15. The system of claim 9, wherein a heat transfer member is further provided to efficiently transfer heat discharged from the reactor vessel.

16. The system of claim 15, wherein a surface of the heat transfer member is chemically processed to increase a surface area thereof.

17. The system of claim 1, wherein the heat exchange section is provided inside the reactor vessel, and
wherein the heat exchange section is a heat exchange section having a shape of cooling an inside of the reactor vessel receiving heat discharged from a reactor coolant system inside the reactor vessel that has received the heat generated from the core.

18. The system of claim 17, wherein the heat exchange section having the shape of cooling the inside of the reactor vessel is connected to an in-containment refueling water storage tank (IRWST) such that refueling water is supplied thereto.

19. The system of claim 18, wherein the heat exchange section having the shape of cooling the inside of the reactor vessel is provided with a second discharge portion, and
wherein the second discharge portion is formed to discharge the refueling water supplied from the in-containment refueling water storage tank (IRWST).

20. The system of claim 1, further comprising an evaporation section connected to the heat exchange section,
wherein the evaporation section is configured to cause heat exchange between an inner fluid of the heat exchange section and an inner fluid of the power production section, and
wherein the system further comprises:
a first circulation part extending from the heat exchange section to the evaporation section such that a fluid circulates therealong; and
a second circulation part extending from the evaporation section to the power production section such that a fluid circulates therealong.

21. The system of claim 20, wherein at least one of the first circulation part and the second circulation part is formed such that a single-phase fluid circulates therealong.

22. The system of claim 1, wherein the heat exchange section further comprises a core catcher, and
wherein the core catcher is provided to receive and cool a corium when the core inside the reactor vessel is melt down.

23. The system of claim 1, wherein the thermoelectric element of the power production section comprises:
a high-temperature part to receive heat from the heat exchange section; and
a low-temperature part to dissipate heat received from the high-temperature part to outside; and
a power production part to produce power using an electromotive force generated by a temperature difference between the high-temperature part and the low-temperature part.

24. The system of claim 23, wherein a coating member is further provided on a surface of the high-temperature part or the low-temperature part to prevent corrosion of the high-temperature part or the low-temperature part.

25. The system of claim 24, wherein a surface of the coating member is chemically processed to increase a surface area thereof.

26. The system of claim 23, wherein the thermoelectric element is further provided with a heat transfer member to efficiently transfer heat discharged from the high-temperature part or the low-temperature part.

27. The system of claim 26, wherein a surface of the heat transfer member is chemically processed to increase a surface area thereof.

28. The system of claim 1, further comprising a condensed water storage section provided at a lower portion of the power production section to collect condensed water generated by condensing the fluid heat-exchanged in the power production section.

29. The system of claim 28, wherein the condensed water in the condensed water storage section is supplied to the heat exchange section by gravity or by a driving force of a pump.

30. A nuclear power plant, comprising:
a reactor vessel;
a heat exchange section to receive heat generated from a core inside the reactor vessel through a fluid; and
a power production section having a thermoelectric element configured to produce electric energy using energy of the fluid whose temperature has increased while receiving the heat of the reactor,
wherein the system is configured to allow the fluid that has received the heat from the core to circulate through the power production section, and to operate even during an accident as well as a normal operation to produce electric power.
